(19) United States
(12) Patent Application Publication
(10) Pub. No.: US 2024/0405153 A1
(43) Pub. Date: Dec. 5, 2024

(54) MEGASONICALLY SOLUTION-PROCESSED NANOSHEET INKS, FABRICATING METHODS, AND APPLICATIONS OF THE SAME

(71) Applicant: NORTHWESTERN UNIVERSITY, Evanston, IL (US)

(72) Inventors: Mark C. Hersam, Wilmette, IL (US); Vinod K. Sangwan, Evanston, IL (US); Sonal V. Rangnekar, Chicago, IL (US)

(21) Appl. No.: 18/802,169

(22) Filed: Aug. 13, 2024

Related U.S. Application Data
(63) Continuation-in-part of application No. PCT/US2023/022664, filed on May 18, 2023.
(60) Provisional application No. 63/533,175, filed on Aug. 17, 2023.
(60) Provisional application No. 63/349,179, filed on Jun. 6, 2022.

(51) Int. Cl. H01L 33/00; B82Y 20/00; B82Y 40/00; C09D 11/52; H01L 33/42

(52) U.S. Cl. CPC H01L 33/0037; B82Y 20/00; B82Y 40/00; C09D 11/52; H01L 33/0041; H01L 33/42

(57) ABSTRACT

One aspect of this invention relates to a method of forming a nanomaterial ink comprising providing an as-prepared (AP) semiconductor ink containing first nanosheets of at least one semiconductor; and megasonically exfoliating the AP semiconductor ink to form a megasonicated semiconductor ink containing second nanosheets of the at least one semiconductor.

### CROSS-REFERENCE TO RELATED PATENT APPLICATIONS

This application claims priority to and the benefit of U.S. Provisional Application No. 63/533,175, filed Aug. 17, 2023, which is incorporated herein in its entirety by reference.

This application is also a continuation in part application of PCT Patent Application No. PCT/US2023/022664, filed May 18, 2023, which itself claims priority to and the benefit of U.S. Provisional Application No. 63/349,179, filed Jun. 6, 2022, which are incorporated herein in their entireties by reference.

### STATEMENT AS TO RIGHTS UNDER FEDERALLY SPONSORED RESEARCH

This invention was made with government support under grant number 70NANB19H005 awarded by the National Institute of Standards and Technology and grant number DMR1720139 awarded by the National Science Foundation. The government has certain rights in the invention.

### FIELD OF THE INVENTION

The present invention generally relates to material science, particularly to electroluminescence from megasonically solution-processed nanosheet inks, fabricating methods, and applications of the same.

### BACKGROUND OF THE INVENTION

The background description provided herein is to present the context of the invention generally. The subject matter discussed in the background of the invention section should not be assumed to be prior art merely due to its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions. Work of the presently named inventors, to the extent it is described in the background of the invention section, as well as aspects of the description that may not otherwise qualify as prior art at the time of filing, are neither expressly nor impliedly admitted as prior art against the invention.

Electroluminescence (EL), which is the conversion of an electrical current into light, is central to diverse technologies such as lighting, displays, data communication, and sensing. Over the last decade, two-dimensional (2D) monolayer semiconductors have been widely studied for electroluminescent devices due to their diverse and tunable optoelectronic and photonic properties. In particular, transition metal dichalcogenides (TMDs) have been of interest due to their layer-dependent bandstructure, direct bandgap at the monolayer limit, strong light-matter interactions, tightly bound excitons, trions, and multi-excitons that can be controlled by strain and doping, solution-processibility for printed optoelectronics, high carrier mobility, and mechanical flexibility. Furthermore, the ability to stack van der Waals materials without the need for lattice matching has enabled a variety of light-emitting device architectures including lateral p-n homojunctions with a split-gate geometry, vertical p-n heterojuctions, and quantum well structures. Light emission through bipolar carrier injection in metal-insulator-semiconductor-metal (MISM) capacitor structures has also been pursued for 2D material light-emitting devices for multiple reasons. First, the light-emitting capacitor structure is simpler to fabricate than p-n heterojunctions or quantum well structures. Second, it avoids stringent materials selection for contact metals since Schottky barriers and work function potential differences can be overcome at moderately high turn-on voltages. Third, the metal-semiconductor-insulator-metal (MSIM) architecture is less sensitive to morphological nonuniformity in the semiconductor layer, which has been exploited in other solution-processed electroluminescent materials such as organic semiconductors.

An outstanding challenge in 2D material optoelectronics is the scalable, solution-based fabrication of large-area electroluminescent devices. For example, the majority of studies on electroluminescent TMDs have utilized mechanically exfoliated nanosheets that cannot be mass-produced. While wafer-scale electroluminescent TMD monolayers can be synthesized by chemical vapor deposition (CVD), these CVD-grown TMD materials suffer from two principal limitations. First, individual monolayers must be delicately transferred from the growth substrate to the device substrate, limiting the manufacturing scalability of this approach. Second, the net fluence of CVD-grown TMD electroluminescent devices is limited by either the atomic-scale thickness of monolayer films or by the low quantum efficiency of thicker TMD films that have indirect bandgaps. In contrast, liquid phase exfoliation has emerged as a low-cost, scalable approach to obtaining TMD nanosheets. However, most studies of solution-processed TMD crystals have resulted in indirect-bandgap few-layer nanosheets with low carrier mobilities in percolating films, which limit their performance in optoelectronic devices such as photodetectors and phototransistors. Consequently, previous attempts to study the EL of solution-processed TMDs have focused on MoS₂ quantum dots or composite materials such as MoS₂—MoO₃ and MoS₂—PEDOT:PSS, all of which have optoelectronic properties that are fundamentally different from monolayer MoS₂ nanosheets.

Therefore, a heretofore unaddressed need exists in the art to address the aforementioned deficiencies and inadequacies.

### SUMMARY OF THE INVENTION

In one aspect, this invention relates to a method of forming a nanomaterial ink. The method comprises providing an as-prepared (AP) semiconductor ink containing first nanosheets of at least one semiconductor; and megasonically exfoliating the AP semiconductor ink to form a megasonicated (MS) semiconductor ink containing second nanosheets of the at least one semiconductor.

In one embodiment, said providing the AP semiconductor ink comprises electrochemically intercalating crystals of the at least one semiconductor to obtain intercalated crystals of the at least one semiconductor; exfoliating the intercalated crystals of the at least one semiconductor in a first solvent using bath sonication to obtain a suspension of exfoliated nanosheets of the at least one semiconductor; and performing solvent transfer via centrifugation to disperse the exfoliated nanosheets of the at least one semiconductor in a second solvent while discarding supernatant, thereby forming the AP semiconductor ink containing the first nanosheets of the at least one semiconductor.

In one embodiment, the at least one layered semiconductor comprises elemental semiconductors including phosphorene, germanene, tellurene, selenene, and/or stanene; monochalcogenides including GeS, InSe, GaTe, PbTe, SnS, and/or SnSe; dichalcogenides including MoS₂, WSe₂, TaS₂, ReS₂, SnS₂ and/or MoTe₂; trichalcogenides including NbSe₃, GaInS₃, Bi₂Se₃, and/or In₂Se₃; 2D semiconducting oxides including MnO₃ and/or V₂O₅; 2D semiconducting metal chalcophosphates including SnP₂Se₆, Sn₂P₂Se₆, NiPS₃, ZnPS₃, FePS₃; 2D metal halides including CrI₃, NiI₂, RuCl₃, VI₃; and/or semiconducting MXenes including Mn₂CO₂, Ti₂C, Sc₂CF₂, and/or Cr₂CF₂.

In one embodiment, the first solvent contains high boiling point organic solvent such as dimethylformamide (DMF), N-methyl-2-pyrrolidone (NMP), propylene carbonate (PC), N-cyclohexyl-2-pyrrolidone (CHP), dimethylcarbonate (DMC), and/or dimethyl sulfoxide (DMSO).

In one embodiment, the first solvent contains a stabilizing agent comprising small molecule stabilizers including bile salts (e.g., sodium cholate), linear chain surfactants (e.g., sodium dodecyl sulfate), and/or pyrene-derivative salts (e.g., 1-pyrenesulfonic acid); and/or polymers including polyvinylpyrrolidone (PVP), Triton X-100, poly(ethylene oxide) (PEO), poly(propylene oxide) (PPO), and/or poloxamers.

In one embodiment, wherein said discarding the supernatant comprises removing excess PVP and precipitating poorly exfoliated semiconductor.

In one embodiment, each of the second nanosheets has a residual polymer (e.g., PVP) coating on its nanosheet surface.

In one embodiment, the second solvent contains water, methanol, ethanol, isopropanol (IPA), butanol, acetone, acetonitrile, triethanolamine, terpineol, Cyrene, dimethylformamide (DMF), N-methyl-2-pyrrolidone (NMP), propylene carbonate (PC), N-cyclohexyl-2-pyrrolidone (CHP), dimethylcarbonate (DMC), and/or dimethyl sulfoxide (DMSO).

In one embodiment, said megasonically exfoliating the AP semiconductor ink is performed in a megasonicator having an acoustic medium containing a water bath, wherein the AP semiconductor ink is poured into a quartz liner tank installed inside the water bath.

In one embodiment, the quartz liner tank has a slant-bottom quartz liner fabricated such wall thickness and slope of the bottom of the quartz liner tank enable maximum transfer of acoustic energy from the water bath to the AP semiconductor ink in the quartz liner tank.

In one embodiment, said megasonically exfoliating the AP semiconductor ink is performed in a megasonicator having an acoustic medium containing a water bath, wherein the AP semiconductor ink is injected into a sealed plastic pouch placed inside the water bath.

In one embodiment, the sealed plastic pouch is solvent resistant and thin enough to ensure maximum transfer of acoustic energy from the water bath to the AP semiconductor ink in the sealed plastic pouch.

In another aspect, this invention relates to a nanomaterial ink that is formed by the above disclosed methods.

In one embodiment, the second nanosheets in the MS semiconductor ink are significantly thinner than the first nanosheets in the AP semiconductor ink.

In one embodiment, the second nanosheets are averagely of monolayer nanosheets, and the first nanosheets are averagely of multilayer nanosheets.

In one embodiment, the second nanosheets have a log-normal mean thickness of about 0.75 nm, and the first nanosheets have a log-normal mean thickness of about 2.3 nm.

In one embodiment, each of the second nanosheets has a residual polymer (e.g., PVP) coating on its nanosheet surface.

In one embodiment, the optical absorbance spectrum of the second nanosheets has A and B exciton peaks that are blue-shifted and narrower compared to those of the first nanosheets.

In one embodiment, the A exciton peak shifts from about 675 nm of the first nanosheets to about 650 nm of the second nanosheets, wherein the A exciton peak of about 650 nm corresponds to that of monolayer nanosheets.

In one embodiment, the monolayer fraction in the MS semiconductor ink is about 68% of the total number of flakes, as calculated from optical absorption spectroscopy analysis, and the monolayer fraction in the AP semiconductor ink is about 2% of the total number of flakes.

In one embodiment, the second nanosheets maintain high crystallinity after megasonication.

In one embodiment, the distance between the in-plane (E¹_{2g}) and out-of-plane (A_{1g}) peaks of Raman spectra of the second nanosheets is about 19.5 cm⁻¹, and wherein the distance between the E¹_{2g} and A_{1g} peaks of Raman spectra of the first nanosheets to 22.5 cm⁻¹.

In one embodiment, the photoluminescence (PL) intensity of the first nanosheets is significantly lower than that of the second nanosheets.

In one embodiment, the A exciton PL peak of the first nanosheets is centered at about 1.8 eV, which is indicative of a trion-dominated resonance that is corresponding to the PL of multilayer nanosheets.

In one embodiment, the spectral shape of the PL of the second nanosheets strongly resembles that of a mechanically exfoliated MoS₂ monolayer.

In one embodiment, the spectral peak of the PL of the second nanosheets is positioned at 1.90 eV, which reflects the A exciton direct bandgap transition at the K point of the Brillouin zone.

In a further aspect, the invention relates to a device comprising at least one element formed of the nanomaterial ink as disclosed above.

In one embodiment, the at least one element is formed by dropcasting of the nanomaterial ink on the substrate.

In one embodiment, the device further comprises electrodes coupled with the at least one element.

In one embodiment, the device is an electronic device including a transistor, a memristor, a diode, a power converter, a sensor, a battery, a resistor, integrated circuit elements, or combinations of them.

In one embodiment, the device is an optoelectronic device including a photodetector, a photosensor, a photodiode, a solar cell, a phototransistor, a light-emitting diode, a laser diode, integrated optical circuit (IOC) elements, a photoresistor, a charge-coupled imaging device, or combinations of them.

In one embodiment, the device is a vertical metal-semiconductor-insulator-metal (MSIM) device.

In one embodiment, the device comprises a gate electrode formed of a transparent conductive material on the glass substrate; a dielectric film formed of Al₂O₃ on the gate electrode by atomic layer deposition (ALD); a semiconductor film formed of the second nanosheets on the dielectric film by dropcasting the nanomaterial ink; and a source electrode formed of a metal material on top of the semiconductor film.

In one embodiment, the transparent conductive material comprises transparent conducting oxides including fluorine doped tin oxide (FTO) and indium tin oxide (ITO).

In one embodiment, the metal material comprises gold, silver, chromium, indium, nickel, aluminum, platinum, palladium, bismuth, and/or titanium.

In one embodiment, the semiconductor film has a thickness in a range of about 1-100 nm.

In one embodiment, the photoluminescence (PL) intensity of the semiconductor film is peaked at 1.89 eV.

In one embodiment, the PL intensity of the semiconductor film increases with increasing film thickness while the PL peak remains at about 1.89 eV.

In one embodiment, the direct-bandgap character of individual monolayer nanosheets is retained in the composite, semiconductor film independently of film thickness.

In one embodiment, the MSIM device is configured to achieve electroluminescence (EL) through oscillatory bipolar carrier injection from the source electrode into the semiconductor film upon application of an alternating current (AC) bias to the gate electrode.

In one embodiment, the EL intensity of the MSIM device increases with the thickness of the semiconductor film.

In one embodiment, in operation, a waveform generator connected to a high bandwidth (1 MHz) voltage amplifier is used to apply a bipolar square wave signal V_{g} to the gate electrode while the source electrode is grounded.

In one embodiment, the square wave is centered about V_{g}=0 V with amplitudes in a range of about ±1 to about ±50 V and frequencies (f) in a range of about 1 to about 600 kHz.

In one embodiment, while applying the square wave with V_{g}=±20 V and f=100 kHz, the semiconductor EL is peaked at about 1.88 eV, indicating that the EL is emitted from a similar excitonic state as the semiconductor PL.

In one embodiment, the EL intensity of the MSIM device is modulatable by the square wave voltage parameters.

In one embodiment, the EL intensity of the MSIM device increases linearly with frequency due to an increased number of voltage transitions per unit time.

In one embodiment, the EL intensity of the MSIM device increases as a function of V_{g} above the turn-on voltage.

In one embodiment, the EL spectra of the semiconductor film red shift slightly with increasing frequency and voltage amplitude.

In one embodiment, measuring EL with decreasing frequency from 400 kHz to 50 kHz results in a blue shifting of the EL peaks, indicating that any charge trapping or heating effects are reversible.

In one embodiment, the semiconductor film shows uniform EL over an entire active device region between the source electrode and the gate electrodes, with the EL intensity increasing with frequency.

In one embodiment, the emission area in the MSIM device is directly determined by the patterned electrodes due to the vertical device architecture and sufficiently conductive semiconductor film with monolayer properties.

In one embodiment, the vertical MSIM device is usable as pixels in miniaturized light sources including micro light emitting diodes (micro-LEDs).

These and other aspects of the present invention will become apparent from the following description of the preferred embodiment taken in conjunction with the following drawings, although variations and modifications therein may be affected without departing from the spirit and scope of the novel concepts of the invention.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1 shows a schematic representation of megasonicated MoS₂ ink preparation according to embodiments of the invention. Panel (a): Electrochemical intercalation of an MoS₂ crystal with tetraheptylammonium cations (THA⁺) in acetonitrile electrolyte. Br₂ is evolved at the Pt foil counter electrode. Panel (b): Bath ultrasonication of intercalated MoS₂ in dimethylformamide (DMF) and polyvinylpyrrolidone (PVP) produces a brown-colored suspension of exfoliated MoS₂ nanosheets. Panel (c): Multiple rounds of centrifugation are used to perform solvent transfer from DMF to isopropanol (IPA) in addition to removing excess PVP and precipitating poorly exfoliated MoS₂. The result of this primary exfoliation step is the as-prepared MoS₂ ink. Panel (d): Megasonication induces secondary exfoliation of the MoS₂ nanosheets down to the monolayer limit with minimal nanosheet lateral size reduction. Panel (e): The final megasonicated MoS₂ ink is bright green and contains a high concentration of MoS₂ monolayers.

FIG. 2 shows comparative characterization of as-prepared (AP) and megasonicated (MS) MoS₂ nanosheets according to embodiments of the invention. Panel (a): The MoS₂ ink changes color from brown to green after megasonication. Panel (b): Representative atomic force microscopy (AFM) images of AP-MoS₂ (top) and MS-MoS₂ (bottom). AFM line profiles extracted from 200 nanosheets of each MoS₂ sample were used to produce comparative histograms of (c) nanosheet length and (d) nanosheet thickness. The average lengths and thicknesses of each sample are indicated on the respective plots. Panel (e): Line profiles of representative AP-MoS₂ and MS-MoS₂ nanosheets. Panel (f): Optical absorbance spectra of AP-MoS₂ and MS-MoS₂ inks. The A and B exciton peaks are indicated. Panel (g): Raman spectra of representative isolated AP-MoS₂ and MS-MoS₂ nanosheets. The in-plane (E¹_{2g}) and out-of-plane (A_{1g}) vibration modes are indicated. Panel (h): Photoluminescence spectra of representative isolated AP-MoS₂ and MS-MoS₂ nanosheets.

FIG. 3 shows characterization of megasonicated MoS₂ nanosheet films according to embodiments of the invention. Panel (a): Schematic of the metal-semiconductor-insulator-metal (MSIM) electroluminescent device. Panel (b): Top-down and (c) cross-sectional scanning electron microscopy images of a about 100-nm-thick dropcasted MS-MoS₂ nanosheet percolating film, respectively. The nanosheet film is partially hanging over the edge of the substrate in each of the SEM images. Panel (d): Photoluminescence spectra of the as-prepared MoS₂ and megasonicated MoS₂ nanosheet films. The inset provides a schematic of the photoluminescence measurement in the MSIM device geometry. Panel (e): Photoluminescence spectra of MS-MoS₂ nanosheet films with different thicknesses.

FIG. 4 shows generating electroluminescence in megasonicated MoS₂ nanosheet films according to embodiments of the invention. Panel (a): Schematic of the MSIM device during operation. Electroluminescence is generated close to the Au contact and emitted through the transparent ITO/glass substrate. Panel (b): Schematic of the AC square wave voltage applied to the ITO gate electrode. Panel (c): Band diagrams for the points labeled 1 and 2 in panel (b). In particular, label 1 is for the transition from positive to negative V_{g}, whereas label 2 is for the transition from negative to positive V_{g}. Panel (d): Electroluminescence spectra of as-prepared and megasonicated MoS₂ films that are both about 70 nm thick.

FIG. 5 shows characterization of electroluminescence in megasonicated MoS₂ films according to embodiments of the invention. Panel (a): Thickness dependence of electroluminescence (EL) in MS-MoS₂ films. Panel (b): EL as a function of the square wave frequency with fixed V_{g}=±20 V. Panel (c): EL as a function of the square wave voltage amplitude with fixed f=100 kHz. Panel (d): Spatial map of EL in an MS-MoS₂ MSIM device, with EL intensity increasing as a function of the square wave frequency.

FIG. 6 shows megasonication details according to embodiments of the invention. Panel (a): Photograph of the quartz liner tank used for large-volume sonication. The tank is filled with 80 mL of as-prepared MoS₂ink. Panel (b): Photograph of heat-sealed plastic pouches used for small volume megasonication experiments. Panel (c): Optical absorbance spectroscopy of various primary and secondary exfoliation experiments for electrochemically exfoliated MoS₂ with the bath sonicator and megasonicator. Intercalated MoS₂ in PVP/DMF cannot be thinned to the monolayer by a single step (primary exfoliation, curves 1 and 2) in either the bath ultrasonicator or megasonicator. Rather, the primary exfoliation of MoS₂ in PVP/DMF in the ultrasonicator must be followed by solvent transfer to IPA (“as prepared” optical absorbance spectra in panel (f) of FIG. 2). Even then, additional processing in the ultrasonicator for up to 18 h does not induce significant secondary exfoliation of the MoS₂ (curve 3). Ultimately, only megasonication of electrochemically exfoliated MoS₂ in IPA allows for secondary exfoliation of nanosheets (curve 4, identical to “megasonicated” optical absorbance spectra in panel (f) of FIG. 2).

FIG. 7 shows additional atomic force microscopy according to embodiments of the invention. Panel (a): Atomic force microscopy image of megasonicated MoS₂ flakes. The sample was annealed in a tube furnace in Ar at 220° C. to remove PVP and other solvents from the nanosheet surface. Panel (b): Line profiles corresponding to the nanosheets marked in (a). The average thickness of all nanosheets is 0.7 nm.

FIG. 8 shows estimation of nanosheet thicknesses from optical absorbance spectra according to embodiments of the invention. Panel (a): Optical absorbance spectra for as-prepared (AP) and megasonicated (MS) MoS₂ inks (from panel (a) of FIG. 3) are plotted as a function of photon energy. The A and B exciton peaks are indicated. Panel (b): The second derivative of the optical absorbance spectra of AP-MoS₂ around the A exciton peak. Lorentzian fits to this curve reveal four populations of nanosheet thicknesses: monolayer (1L), bilayer (2L), trilayer (3L), and multilayer (4L+). Panel (c): The second derivative of the optical absorbance spectra of MS-MoS₂ around the A exciton peak. Lorentzian fits to this curve reveal two populations of nanosheet thicknesses: monolayer (1L) and bilayer (2L). Panel (d): Percentage of nanosheets in AP-MoS₂ and MS-MoS₂ dispersions at various thicknesses, estimated from the fit areas shown in panels (b) and (c).

FIG. 9 shows megasonicated MoS₂ film formation via dropcasting according to embodiments of the invention. Optical images of various dropcasted MS-MoS₂ films. A severe coffee ring effect is observed when dropcasting inks that only have isopropanol (IPA) as a solvent. Adding 20% H₂O to the ink enables more uniform films from dropcasting. Multiple layers (1-3L shown here) of MoS₂ ink can be dropcasted to adjust the film thickness.

FIG. 10 shows thermal annealing of megasonicated MoS₂ nanosheet films according to embodiments of the invention. Panel (a): Photoluminescence, and Panel (b): normalized photoluminescence of megasonicated MoS₂ films as casted and after annealing in an Ar tube furnace at 400° C. for 30 min.

FIG. 11 shows photoluminescence and electroluminescence of as-prepared MoS₂ films according to embodiments of the invention. Panels (a)-(b): Raw and normalized PL spectra, respectively, of a about 70-nm-thick AP-MoS₂ film acquired at different laser power filters. The PL counts increase and the peak red shifts from 1.75 eV to 1.70 eV with increasing power. Panel (c): EL spectra of AP-MoS₂ at various frequencies of the gate voltage signal with fixed gate voltage amplitude of V_{g}=±20 V. The EL counts are much lower than MS-MoS₂ films of similar thickness.

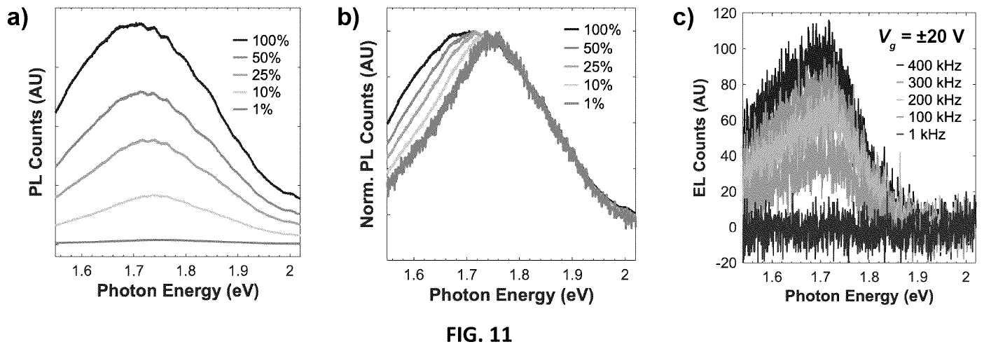

FIG. 12 shows fitting megasonicated MoS₂ photoluminescence and electroluminescence spectra according to embodiments of the invention. Panel (a): PL and Panel (b): EL spectra of a 70-nm-thick MS-MoS₂ film were fit with two Lorentzians to extract the neutral exciton (X) and negatively charged trion (X⁻) emission contributions. The trion intensity is slightly larger in the EL spectra.

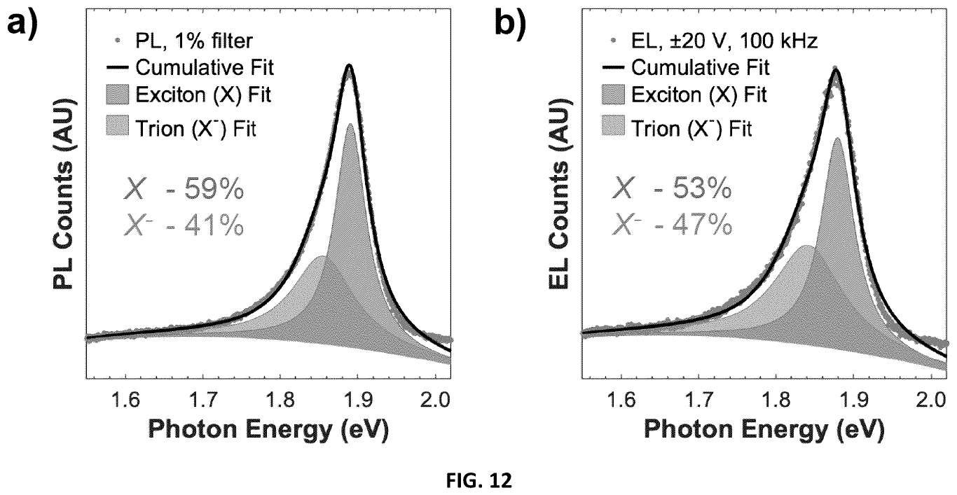

FIG. 13 shows frequency, voltage, and thickness dependence trends in the electroluminescence of megasonicated MoS₂ films according to embodiments of the invention. Panel (a): Integrated EL intensity as a function of the frequency of the gate voltage signal at fixed gate voltage amplitude V_{g}=±20. The intensity increases linearly with frequency but begins to roll off at f>100 kHz. Panel (b): Integrated EL intensity in counts/cycle as a function of frequency. The cycle-normalized EL intensity decreases with frequency due to distortion of the V_{g} square waveform. Panel (c): Integrated EL intensity and (d) integrated EL intensity in counts per cycle as a function of gate voltage amplitude V_{g} for fixed f=100 kHz. The intensity increases linearly with V_{g} for both cases.

FIG. 14 shows quantifying redshifts in megasonicated MoS₂ electroluminescence according to embodiments of the invention. Panel (a): The peak energy of EL as a function of the frequency of the applied gate voltage signal. The peak location red shifts linearly with increasing frequency, ranging from ≈1.885 eV at 5 kHz to ≈1.865 eV at 400 kHz. The dotted line serves as a guide to the eye. Panel (b): The EL spectra for the 42-nm-thick MS-MoS₂ film were fit to Lorentzian curves representing the trion and exciton contributions to EL (as in panel (b) of FIG. 11). The peak positions of the trion and exciton fits are plotted as a function of frequency on the left y-axis. The ratio of the exciton intensity to trion intensity versus frequency is plotted on the right y-axis. The contribution of the neutral exciton decreases with increasing frequency. Panel (c): EL spectra of a 70-nm-thick MS-MoS₂ film were acquired while decreasing the frequency of the gate voltage signal for successive measurements. The EL peaks blue shift with decreasing frequency, indicating that the trion emission is a consequence of temporary Joule heating or charge trapping in the MoS₂ film.

### DETAILED DESCRIPTION OF THE INVENTION

The invention will now be described more fully hereinafter with reference to the accompanying drawings, in which exemplary embodiments of the invention are shown. However, this invention may be embodied in many different forms and should not be construed as limited to the embodiments set forth herein. Rather, these embodiments are provided so that this specification will be thorough and complete and fully convey the invention's scope to those skilled in the art. Like reference numerals refer to like elements throughout.

The terms used in this specification generally have their ordinary meanings in the art, within the context of the invention, and in the specific context where each term is used. Certain terms used to describe the invention are discussed below, or elsewhere in the specification, to provide additional guidance to the practitioner regarding the description. For convenience, certain terms may be highlighted, for example using italics and/or quotation marks. The use of highlighting has no influence on the scope and meaning of a term; the scope and meaning of a term are the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that, as used in the description herein and throughout the claims that follow, the meaning of “a”, “an”, and “the” includes plural reference unless the context clearly dictates otherwise. Also, it will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, or section without departing from the invention's teachings.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures. is turned over, elements described as being on the “lower” side of other elements would then be oriented on “upper” sides of the other elements. The exemplary term “lower”, can, therefore, encompasses both an orientation of “lower” and “upper,” depending on the particular orientation of the figure. Similarly, if the device in one of the figures is turned over, elements described as “below” or “beneath” other elements would then be oriented “above” the other elements. Therefore, the exemplary terms “below” or “beneath” can encompass both an orientation of above and below.

It will be further understood that the terms “comprises” and/or “comprising,” or “includes” and/or “including” or “has” and/or “having”, or “carry” and/or “carrying,” or “contain” and/or “containing,” or “involve” and/or “involving, and the like are to be open-ended, i.e., to mean including but not limited to. When used in this specification, they specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

As used in this specification, “around”, “about”, “approximately” or “substantially” shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated.

As used in this specification, the phrase “at least one of A, B, and C” should be construed to mean a logical (A or B or C), using a non-exclusive logical OR. As used herein, the term “and/or” includes any and all combinations of one or more of the associated listed items.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in a different order (or concurrently) without altering the principles of the invention.

Electroluminescence (EL), which is the conversion of an electrical current into light, is central to diverse technologies such as lighting, displays, data communication, and sensing. Over the last decade, two-dimensional (2D) monolayer semiconductors—particularly, transition metal dichalcogenides (TMDs)—have been widely studied for EL devices due to their diverse and tunable optoelectronic and photonic properties. However, challenges in isolating optoelectronically active TMD monolayers using scalable liquid phase exfoliation have precluded the realization of electroluminescence in large-area, solution-processed TMD films.

Several techniques have been attempted to obtain monolayer-rich molybdenum disulfide (MoS₂) inks. Lithium intercalation of MoS₂ powders or crystals is a decades-old approach to obtain a high yield of MoS₂ monolayers. However, this approach induces a phase change from semiconducting 2H-MoS₂ to conductive 1T-MoS₂, resulting in entirely different structural, optical, and electronic properties that are not suitable for light-emitting devices. Techniques to reverse the phase change do not fully recover semiconducting 2H-MoS₂. More recently, standard electrochemical exfoliation has been reported to yield MoS₂ inks containing monolayers; however, the photoluminescence of these inks does not show the direct bandgap of monolayer MoS2, which undermines the claim of monolayer-rich inks. More broadly, acoustic-based exfoliation techniques such as horn-tip and bath sonication can be used to produce 2D material monolayers. However, the monolayer yield is quite low and the nanosheet length is significantly smaller (about 100 nm) than that of electrochemically exfoliated materials (0.5-2 μm). Monolayer enrichment through techniques such as liquid cascade centrifugation and density gradient ultracentrifugation is time-consuming and ultimately discards over 90% of the exfoliated material.

Large-area electroluminescence from TMD films has been attempted using CVD-gr own monolayer films of MoS₂ and WS₂ with a vertical capacitor device geometry. However, the electroluminescence in these devices is spatially localized near the contact edges. Large-area EL (millimeter-scale) is obtained by creating a dense array of source electrodes that limits the overall emitting area. Furthermore, the monolayer thickness in these devices also limits the net light output. In our invention, megasonically exfoliated MoS₂ for the vertical capacitor device enables planar and uniform light-emission in a proof-of-concept 100 μm×300 μm area using a single continuous source electrode. There are no fundamental limits to scaling this process to larger areas.

Previous attempts to study the EL of solution-processed TMDs have focused on MoS₂ quantum dots or composite materials such as MoS₂—MoO₃ and MoS₂—PEDOT:PSS, all of which have optoelectronic properties that are inferior to monolayer MoS₂ nanosheets.

Among the previously investigated TMD solution processing methods, electrochemical exfoliation has yielded the best device performance in percolating nanosheet films for thin-film transistors, photodetectors, and memristors. Electrochemically exfoliated TMD inks are notable for their superior nanosheet size uniformity compared to inks obtained through alternative liquid phase exfoliation methods such as horn sonication or shear mixing. The high degree of nanosheet size uniformity results in solution-processed films with exceptional percolating charge transport, yielding carrier mobilities on the order of 10 cm² V⁻¹ s⁻¹, which is comparable to that of mechanically exfoliated MoS₂. While most previous studies have utilized as-prepared electrochemically exfoliated MoS₂ inks in isopropanol (IPA), we have recently shown that secondary exfoliation with megasonication (i.e., bath sonication at megahertz frequencies) further thins electrochemically exfoliated MoS₂ nanosheets down to the monolayer limit, which is disclosed in PCT Patent Application No. PCT/US2023/022664, which is incorporated herein in their entireties by reference. Importantly, megasonication enriches the monolayer concentration of the MoS₂ ink by converting thicker nanosheets to monolayers, unlike post-exfoliation centrifugal separation processes that discard thicker material, thus providing significantly higher monolayer yields and scalability. The mechanistic differences between ultrasonic and megasonic exfoliation of 2D materials are discussed in detail in the section of METHODS AND MATERIALS. Briefly, while traditional liquid phase exfoliation processes based on violent inertial cavitation at kilohertz sonication frequencies cause nanosheet fragmentation in addition to exfoliation, the gentler and more stable cavitation produced with megahertz sonication frequencies results in nanosheet delamination with minimal fracture. Due to the high concentration of monolayer MoS₂ nanosheets with micron-scale lateral sizes, megasonically exfoliated and printed MoS₂ films have yielded the highest reported responsivities among all-printed, visible-light photodetectors, suggesting that megasonication could also enable other solution-processed TMD optoelectronic devices.

In this disclosure, we overcome these limitations and demonstrate EL from MoS₂ nanosheet films by developing and employing a monolayer rich MoS₂ ink produced by electrochemical intercalation and megasonic exfoliation. Megasonicated MoS₂ films demonstrate characteristic monolayer MoS₂ photoluminescence and electroluminescence spectral peaks, with emission intensity increasing with film thickness over the range of 10-70 n m. Furthermore, employing a vertical light-emitting capacitor geometry enables uniform electroluminescence in large-area devices. These novel properties are attributed to a polymer coating on the MoS₂ monolayer surfaces that impedes strong electronic coupling between adjacent nanosheets. Additionally, these results indicate that megasonically exfoliated MoS₂ monolayers retain their direct-bandgap character in thick electrically percolating thin films even following multi-step solution processing. Overall, this work establishes megasonicated MoS₂ inks as an additive manufacturing platform for flexible, patterned, and miniaturized light sources that can likely be expanded to other TMD semiconductors.

Inexpensive, high-quality 2D materials must be available to drive commercial applications. The invention of a scalable megasonication process to obtain a high yield of MoS₂ monolayers via solution processing achieves this goal. Simultaneously, compelling applications must be developed to utilize these inks. Towards this end, scalably manufactured films of megasonicated MoS₂ nanosheets may be utilized in a number of light-emitting technologies.

Without intent to limit the scope of the invention, exemplary embodiments of the invention are given below.

In one aspect, this invention relates to a method of forming a nanomaterial ink. The method comprises providing an as-prepared (AP) semiconductor ink containing first nanosheets of at least one semiconductor; and megasonically exfoliating the AP semiconductor ink to form a megasonicated (MS) semiconductor ink containing second nanosheets of the at least one semiconductor.

It should be noted that the term “first nanosheets”, used in the disclosure, refers to nanosheets of the at least one semiconductor in the AP semiconductor ink, which are produced by the primary exfoliation of intercalated crystals of the at least one semiconductor using bath sonication, and the term “second nanosheets”, used in the disclosure, refers to nanosheets of the at least one semiconductor in the MS semiconductor ink, which are produced by the secondary exfoliation of the AP semiconductor ink using megasonication.

In one embodiment, said providing the AP semiconductor ink comprises electrochemically intercalating crystals of the at least one semiconductor to obtain intercalated crystals of the at least one semiconductor; exfoliating the intercalated crystals of the at least one semiconductor in a first solvent using bath sonication to obtain a suspension of exfoliated nanosheets of the at least one semiconductor; and performing solvent transfer via centrifugation to disperse the exfoliated nanosheets of the at least one semiconductor in a second solvent while discarding supernatant, thereby forming the AP semiconductor ink containing the first nanosheets of the at least one semiconductor.

In one embodiment, the at least one layered semiconductor comprises elemental semiconductors including phosphorene, germanene, tellurene, selenene, and/or stanene; monochalcogenides including GeS, InSe, GaTe, PbTe, SnS, and/or SnSe; dichalcogenides including MoS₂, WSe₂, TaS₂, ReS₂, SnS₂ and/or MoTe₂; trichalcogenides including NbSe₃, GaInS₃, Bi₂Se₃, and/or In₂Se₃; 2D semiconducting oxides including MnO₃ and/or V₂O₅; 2D semiconducting metal chalcophosphates including SnP₂Se₆, Sn₂P₂Se₆, NiPS₃, ZnPS₃, FePS₃; 2D metal halides including CrI₃, NiI₂, RuCl₃, VI₃; and/or semiconducting MXenes including Mn₂CO₂, Ti₂C, Sc₂CF₂, and/or Cr₂CF₂.

In one embodiment, the first solvent contains dimethylformamide (DMF), N-methyl-2-pyrrolidone (NMP), propylene carbonate (PC), N-cyclohexyl-2-pyrrolidone (CHP), dimethylcarbonate (DMC), and/or dimethyl sulfoxide (DMSO).

In one embodiment, the first solvent contains a stabilizing agent comprising small molecule stabilizers including bile salts (e.g., sodium cholate), linear chain surfactants (e.g., sodium dodecyl sulfate), and/or pyrene-derivative salts (e.g., 1-pyrenesulfonic acid); and/or polymers including polyvinylpyrrolidone (PVP), Triton X-100, poly(ethylene oxide) (PEO), poly(propylene oxide) (PPO), and/or poloxamers.

In one embodiment, wherein said discarding the supernatant comprises removing excess PVP and precipitating poorly exfoliated semiconductor.

In one embodiment, each of the second nanosheets has a residual PVP coating on its nanosheet surface.

In one embodiment, the second solvent contains water, methanol, ethanol, isopropanol (IPA), butanol, acetone, acetonitrile, triethanolamine, terpineol, Cyrene, dimethylformamide (DMF), N-methyl-2-pyrrolidone (NMP), propylene carbonate (PC), N-cyclohexyl-2-pyrrolidone (CHP), dimethylcarbonate (DMC), and/or dimethyl sulfoxide (DMSO).

In one embodiment, said megasonically exfoliating the AP semiconductor ink is performed in a megasonicator having an acoustic medium containing a water bath, wherein the AP semiconductor ink is poured into a quartz liner tank installed inside the water bath.

In one embodiment, the quartz liner tank has a slant-bottom quartz liner fabricated such wall thickness and slope of the bottom of the quartz liner tank enable maximum transfer of acoustic energy from the water bath to the AP semiconductor ink in the quartz liner tank.

In one embodiment, said megasonically exfoliating the AP semiconductor ink is performed in a megasonicator having an acoustic medium containing a water bath, wherein the AP semiconductor ink is injected into a sealed plastic pouch placed inside the water bath.

In one embodiment, the sealed plastic pouch is solvent resistant and thin enough to ensure maximum transfer of acoustic energy from the water bath to the AP semiconductor ink in the sealed plastic pouch.

In another aspect, this invention relates to a nanomaterial ink that is formed by the above disclosed methods.

In one embodiment, the second nanosheets in the MS semiconductor ink are significantly thinner than the first nanosheets in the AP semiconductor ink.

In one embodiment, the second nanosheets are averagely of monolayer nanosheets, and the first nanosheets are averagely of multilayer nanosheets.

In one embodiment, the second nanosheets have a log-normal mean thickness of about 0.75 nm, and the first nanosheets have a log-normal mean thickness of about 2.3 nm.

In one embodiment, each of the second nanosheets has a residual polymer (e.g., PVP) coating on its nanosheet surface.

In one embodiment, the optical absorbance spectrum of the second nanosheets has A and B exciton peaks that are blue-shifted and narrower compared to those of the first nanosheets. It should be noted that the term “A exciton PL peak”, used in the disclosure, refers to a photoluminescence (PL) emission feature that corresponds to a ground state exciton in monolayer transition metal dichalcogenides (TMDs), and the term “B exciton PL peak”, used in the disclosure, refers to another PL emission feature that corresponds to higher spin-orbit split state exciton in monolayer TMDs.

In one embodiment, the A exciton peak shifts from about 675 nm of the first nanosheets to about 650 nm of the second nanosheets, wherein the A exciton peak of about 650 nm corresponds to that of monolayer nanosheets.

In one embodiment, the monolayer fraction in the MS semiconductor ink is about 68% of the total number of flakes, as calculated from optical absorption spectroscopy analysis, and the monolayer fraction in the AP semiconductor ink is about 2% of the total number of flakes.

In one embodiment, the second nanosheets maintain high crystallinity after megasonication.

In one embodiment, the distance between the in-plane (E¹_{2g}) and out-of-plane (A_{1g}) peaks of Raman spectra of the second nanosheets is about 19.5 cm⁻¹, and wherein the distance between the E¹_{2g} and A_{1g} peaks of Raman spectra of the first nanosheets to 22.5 cm⁻¹.

In one embodiment, the photoluminescence (PL) intensity of the first nanosheets is significantly lower than that of the second nanosheets.

In one embodiment, the A exciton PL peak of the first nanosheets is centered at about 1.8 eV, which is indicative of a trion-dominated resonance that is corresponding to the PL of multilayer nanosheets.

In one embodiment, the spectral shape of the PL of the second nanosheets strongly resembles that of a mechanically exfoliated MoS₂ monolayer.

In one embodiment, the spectral peak of the PL of the second nanosheets is positioned at 1.90 eV, which reflects the A exciton direct bandgap transition at the K point of the Brillouin zone.

In a further aspect, the invention relates to a device comprising at least one element formed of the nanomaterial ink as disclosed above.

In one embodiment, the at least one element is formed by dropcasting of the nanomaterial ink on the substrate.

In one embodiment, the device further comprises electrodes coupled with at least one element.

In one embodiment, the device is an electronic device including a transistor, a memristor, a diode, a power converter, a sensor, a battery, a resistor, integrated circuit elements, or combinations of them.

In one embodiment, the device is an optoelectronic device including a photodetector, a photosensor, a photodiode, a solar cell, a phototransistor, a light-emitting diode, a laser diode, integrated optical circuit (IOC) elements, a photoresistor, a charge-coupled imaging device, or combinations of them.

In one embodiment, the device is a vertical metal-semiconductor-insulator-metal (MSIM) device.

In one embodiment, the device comprises a gate electrode formed of a transparent conductive material on the glass substrate; a dielectric film formed of Al₂O₃ on the gate electrode by atomic layer deposition (ALD); a semiconductor film formed of the second nanosheets on the dielectric film by dropcasting the nanomaterial ink; and a source electrode formed of a metal material on top of the semiconductor film.

In one embodiment, the transparent conductive material comprises transparent conducting oxides including fluorine doped tin oxide (FTO) and indium tin oxide (ITO).

In one embodiment, the metal material comprises gold, silver, chromium, indium, nickel, aluminum, platinum, palladium, bismuth, and/or titanium.

In one embodiment, the semiconductor film has a thickness in a range of about 1-100 nm.

In one embodiment, the photoluminescence (PL) intensity of the semiconductor film is peaked at 1.89 eV.

In one embodiment, the PL intensity of the semiconductor film increases with increasing film thickness while the PL peak remains at about 1.89 eV.

In one embodiment, the direct-bandgap character of individual monolayer nanosheets is retained in the composite, semiconductor film independently of film thickness.

In one embodiment, the MSIM device is configured to achieve electroluminescence (EL) through oscillatory bipolar carrier injection from the source electrode into the semiconductor film upon application of an alternating current (AC) bias to the gate electrode.

In one embodiment, the EL intensity of the MSIM device increases with the thickness of the semiconductor film.

In one embodiment, in operation, a waveform generator connected to a high bandwidth (1 MHz) voltage amplifier is used to apply a bipolar square wave signal V_{g} to the gate electrode while the source electrode is grounded.

In one embodiment, the square wave is centered about V_{g}=0 V with amplitudes in a range of about ±1 to about ±50 V and frequencies (f) in a range of about 1 to about 600 kHz.

In one embodiment, while applying the square wave with V_{g}=±20 V and f=100 kHz, the semiconductor EL is peaked at about 1.88 eV, indicating that the EL is emitted from a similar excitonic state as the semiconductor PL.

In one embodiment, the EL intensity of the MSIM device is modulatable by the square wave voltage parameters.

In one embodiment, the EL intensity of the MSIM device increases linearly with frequency due to an increased number of voltage transitions per unit time.

In one embodiment, the EL intensity of the MSIM device increases as a function of V_{g} above the turn-on voltage.

In one embodiment, the EL spectra of the semiconductor film red shift slightly with increasing frequency and voltage amplitude.

In one embodiment, measuring EL with decreasing frequency from 400 kHz to 50 kHz results in a blue shifting of the EL peaks, indicating that any charge trapping or heating effects are reversible.

In one embodiment, the semiconductor film shows uniform EL over an entire active device region between the source electrode and the gate electrodes, with the EL intensity increasing with frequency.

In one embodiment, the emission area in the MSIM device is directly determined by the patterned electrodes due to the vertical device architecture and sufficiently conductive semiconductor film with monolayer properties.

In one embodiment, the vertical MSIM device is usable as pixels in miniaturized light sources including micro light emitting diodes (micro-LEDs).

Among other things, the invention provides at least the following advantages.

A scalable method has been achieved for megasonication of electrochemically exfoliated van der Waals crystals. The process yields nanosheets with a tight distribution of thickness (tₐᵥₑ≈0.7 nm for MoS₂) with a large fraction (about 70%) of monolayers. This megasonication method utilizes a commercially available megasonic cleaner for a high net yield. This “secondary exfoliation” technique has advantages over “primary exfoliation” techniques such as tip sonication, bath ultrasonication, and shear mixing that produce a large distribution of nanosheet sizes in dispersions. In this manner, megasonically exfoliation conserves the mass of exfoliated material in solution and increases the yield of monolayers compared to centrifugal processing techniques such as liquid cascade centrifugation and density gradient ultracentrifugation.

A high yield of MoS₂ monolayers from the megasonication process allows the realization of technology that relies exclusively on the high quantum yield of optical transitions across the direct electronic bandgap such as electroluminescent (EL) or light-emitting devices. Composite films from megasonicated MoS₂ also yield a strong photoluminescence (PL) spectrum that matches isolated MoS₂ monolayers.

The solution-processed, electroluminescent monolayer MoS₂ inks are compatible with scalable manufacturing techniques, such as ink printing, to fabricate large-area light-emitting devices. Conventionally, electroluminescence in 2D semiconductors has been demonstrated with mechanically exfoliated nanosheets for proof-of-concept devices; however, these devices are not scalable due to the labor-intensive nanosheet synthesis approach. Chemical vapor deposition (CVD) has also been utilized to obtain large-area monolayer films of 2 D nanosheets for EL, but this method requires several cleanroom-based film transfer and patterning steps that limit the quality and scalability of EL technology. Moreover, CVD monolayers are only 1-nm-thick which limits the net optical output of EL. Here, megasonication allows thicker percolating MoS₂ films (approaching 100 nm in thickness) that retain the direct bandgap of monolayer MoS₂ that is essential for high quantum yield EL.

Fabricating vertical light-emitting capacitors with electroluminescent megasonicated MoS₂ inks uniquely enables large-area, planar EL devices. Other attempts to utilize this capacitor architecture with large-area CVD-grown TMD films have resulted in spatially localized electroluminescence at electrode edges, requiring a high electrode density to mimic planar electroluminescence where electrodes disrupt the spatial homogeneity of the light output.

The PL and EL intensities of megasonicated MoS₂ vertical light-emitting capacitors (LECs) scale with increasing MoS₂ nanosheet film thickness, which is a notable advance for practical technologies. As an example, organic EL molecules used in conventional solution-processed light-emitting diodes (LEDs) must be assembled in uniform, thick films to maximize light emission. Percolating films of 2D materials such as MoS₂ have similar charge transport characteristics as organic molecules, but scalability in the vertical direction is the key to realizing practical light-emitting devices. In this work, there is sufficient charge carrier mobility in the vertical direction in megasonicated MoS₂ films to allow band bending to occur at the metal contact. The band bending is reversed at a high rate by the application of an alternating current (AC) voltage at the other contact in a two-probe vertical LEC. Furthermore, the polymer coating on the surface of MoS₂ monolayers, which is a consequence of the initial electrochemical exfoliation process, impedes undesirable electronic coupling between nanosheets and maintains monolayer characteristics in bulk films. Consequently, light emission (both PL and EL) is obtained from the depth of the nanosheet film determined by the depletion region and extinction coefficient of the percolating MoS₂ film.

The invention may have widespread applications in electroluminescent devices, light-emitting capacitors, photodetectors, flexible photodetectors, two-dimensional transistors, thin-film transistors, neuromorphic computing devices, printed electronics, micro-pixel flat panel displays, nanomaterials synthesis, printed optoelectronics, wearable sensors, and the like.

These and other aspects of the invention are further described below. Without intent to limit the scope of the invention, exemplary instruments, apparatus, methods, and their related results according to the embodiments of the invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### Example

### Electroluminescence from Megasonically Solution-Processed MoS₂ Nanosheet Films

Due to their unique optoelectronic properties, monolayer two-dimensional (2D) transition metal dichalcogenides (TMDs) have attracted significant attention for electroluminescent devices. However, challenges in isolating optoelectronically active TMD monolayers using scalable liquid phase exfoliation has precluded electroluminescence in large-area, solution-processed TMD films.

In this example, we overcome these limitations and demonstrate electroluminescence from molybdenum disulfide (MoS₂) nanosheet films by employing a monolayer rich MoS₂ ink produced by electrochemical intercalation and megasonic exfoliation. Characteristic monolayer MoS₂ photoluminescence and electroluminescence spectral peaks at 1.88-1.90 eV are observed in megasonicated MoS₂ films with the emission intensity increasing with film thickness over the range of 10-70 nm. Furthermore, employing a vertical light-emitting capacitor architecture enables uniform electroluminescence in large-area devices. These results indicate that megasonically exfoliated MoS₂ monolayers retain their direct bandgap character in electrically percolating thin films even following multi-step solution processing. Overall, this work establishes megasonicated MoS₂ inks as an additive manufacturing platform for flexible, patterned, and miniaturized light sources that can likely be expanded to other TMD semiconductors.

Specifically, we employ megasonication to achieve electroluminescence (EL) from large-area, solution-processed MoS₂ nanosheet films. Unlike previous work that achieved megasonication using a low-volume atomizer chamber, this study utilizes a large-volume megasonication bath that increases processing throughput and results in a high fraction of monolayer MoS₂ nanosheets that exhibit a strong photoluminescence (PL) spectral peak at 1.90 eV. Moreover, even 70-nm-thick dropcasted films produced from the megasonicated MoS₂ inks display strong PL peaked at 1.89 eV, confirming that the monolayer MoS₂ optoelectronic response is preserved in large-area percolating films. By integrating large-area percolating films of megasonicated MoS₂ with a parallel-plate metal-semiconductor-insulator-metal (MSIM) capacitor geometry, an alternating current (AC) biasing scheme can generate EL with tunable intensity controlled by the film thickness in addition to the AC voltage amplitude and frequency. The EL spectra from these large-area devices possess peaks at 1.88 eV that closely match the PL spectra, thus confirming that monolayer MoS₂ properties are preserved in thin films in the MSIM architecture. Overall, this work establishes a scalable, solution-based pathway for producing large-area EL devices based on monolayer TMDs.

### Methods and Materials

### Ink Preparation:

A synthetic MoS₂ crystal (2D Semiconductors) was divided into narrow slivers (approx. 0.5 mm wide×2 cm long×1 mm thick) using a razor blade. An electrochemical cell was constructed with a sliver of MoS₂ as the working electrode, platinum foil as the counter electrode, and an electrolyte of 5 mg/mL tetraheptylammonium bromide (99%, Acros Organics/Thermo Scientific Chemicals) in acetonitrile (99.8%, Sigma-Aldrich). A fixed potential of −10 V was applied across the cell for 1-2 hours to drive intercalation. Next, the expanded crystal sliver was dried in air and chopped with a razor blade into a chunky powder. The aggregate powder of several crystal slivers was bath sonicated in 40 mL of 0.2 M polyvinylpyrrolidone (PVP) (powder, average Mw about 29,000, Sigma-Aldrich) in dimethylformamide (DMF) (anhydrous, 99.8%, Sigma-Aldrich) for 90 min. The exfoliated slurry was washed with isopropanol (IPA; ACS Grade, Fisher Chemical) three times by pelletizing the MoS₂ by ultracentrifugation, discarding the supernatant, and redispersing the pellet in fresh IPA. Finally, the dispersion was centrifuged at 7500 rpm for 5 min (Avanti J26XPI with a JS-7.5 rotor) to obtain the as-prepared MoS₂ nanosheet ink.

### Megasonication:

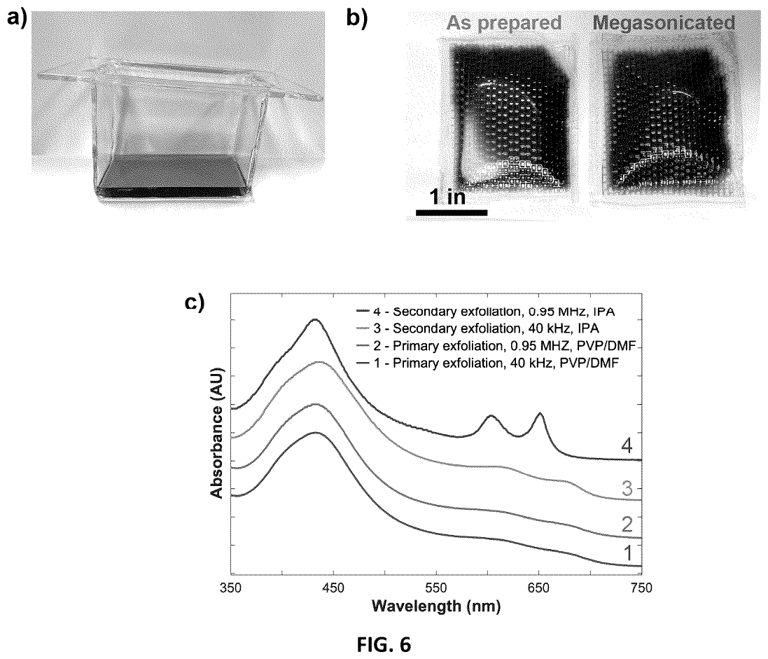

To further increase the monolayer nanosheet concentration, the MoS₂ ink was subjected to megasonication. A megasonic cleaner and generator (PCT Systems Megasonic Hyperclean) operating at about 0.95 MHz were utilized for secondary exfoliation experiments. The acoustic medium was water, and the water bath temperature was regulated with an ultrasonic bath cooling coil (Fisher brand) attached to a chiller operating at 5-20° C. The megasonicator was operated at full power with a mux time of 10 ms. Two techniques were utilized to contain the MoS₂ ink during megasonication. For volumes >50 mL, the ink was poured into a quartz linear tank (panel (a) of FIG. 6). The slant-bottom quartz liner was fabricated such the wall thickness and slope of the bottom enable the maximum transfer of acoustic energy. For volumes <10 mL, the ink was injected into a heat-sealed plastic pouch (panel (b) of FIG. 6). These pouches were solvent resistant and thin enough to ensure maximum transfer of acoustic energy between the water bath and the ink. Depending on the volume and concentration of the ink, maximum megasonic exfoliation was observed after 2-72 hours of megasonication. The degree of monolayer conversion in the ink was tracked via optical absorbance spectroscopy (Agilent Cary 5000 Spectrophotometer), as shown in panel (c) of FIG. 6.

### Device Fabrication:

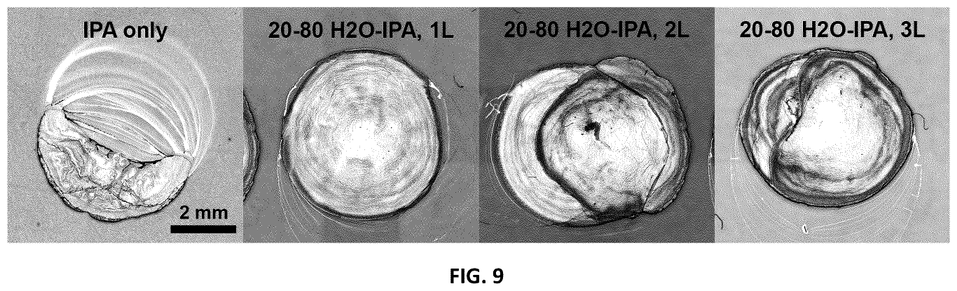

Glass chips coated with a thin layer of indium tin oxide (ITO) were obtained from Thin Film Devices, Inc. (Anaheim, California). The ITO chips were cleaned by successive bath sonication in acetone, isopropanol, and deionized water. A 60-nm-thick film of Al₂O₃ was grown on part of the ITO chip via atomic layer deposition (Cambridge Nanotech Savannah 5100 ALD). Next, the MoS₂ ink was dropcasted onto the region of the chip covered in Al₂O₃(FIG. 9). Gold electrodes were fabricated by physical vapor deposition through a shadow mask to contact the ITO and the MoS₂ films, forming a metal-semiconductor-insulator-metal (MSIM) stack.

### Photoluminescence Spectroscopy:

Photoluminescence (PL) spectra were obtained using a Horiba XploRa PLUS confocal microscope with a 473 nm laser and 600 mm⁻¹ grating. All point spectra were acquired at 20× magnification (NA=0.4) at 1% laser power (92 μW) with 0.5 s acquisition times and averaged over 10 accumulations.

### Electroluminescence Spectroscopy:

Electroluminescence (EL) of the MoS₂ films was measured at 20× magnification (NA=0.4) using a Horiba XploRa PLUS confocal microscope coupled with a spectrometer via a 600 mm⁻¹ grating. A waveform generator (Agilent 33500B Series Trueform Waveform Generator) was used to output a square bipolar wave with programmed peak-to-peak amplitude (Vpp) of 50 mV to 1.5 V. A voltage amplifier (Thorlabs HVA200 High Voltage Amplifier) was used to amplify this signal 40-fold such that the absolute applied potential ranged from 1 V to 30 V. The frequency of the waveform was adjusted between 1 kHz and 500 kHz. An oscilloscope (Tektronix TBS 2000 Series Digital Oscilloscope) was used to verify the applied potential and identify leaky and short circuits. EL spectra shown in this work were obtained with an acquisition time of 20 s and averaged over 5 accumulations. Spatial visualization of EL was obtained at 5× magnification using a CMOS camera (Teledyne Photometrics PRIME BSI Express Scientific CMOS).

### Atomic Force Microscopy:

The thickness of MoS₂ nanosheets was studied with atomic force microscopy (AFM). Dilute aliquots of MoS₂ in IPA were prepared and dropcasted onto 300 nm SiO₂ wafer chips. To remove excess PVP on the surface of nanosheets, the chips were annealed under Ar flow in a tube furnace (Thermo Scientific Lindberg Blue M) at 220° C. for 1 h. Isolated nanosheets were characterized by atomic force microscopy (Oxford Instruments Asylum Research Cypher AFM) in tapping mode using Si cantilevers with a resonance frequency of about 320 kHz. AFM images were post-processed in Gwyddion, and line profiles across isolated nanosheets were obtained. A MATLAB® program was used to extract the nanosheet thicknesses and lengths from the line profile data.

### Raman Spectroscopy:

Raman spectra were obtained at 100× magnification (NA=0.9) using a Horiba XploRa PLUS confocal microscope with a 473 nm laser and 2400 mm⁻¹ grating. Spectra were acquired at 10% laser power (1.13 mW) with 10 s acquisition time and averaged over 6 accumulations.

### Scanning Electron Microscopy:

Morphological characterization of the MoS₂ film was performed with top-down and cross-sectional scanning electron microscopy (Hitachi SU8030 SEM). Samples were prepared by dropcasting MoS₂ ink on glass slides and cleaving through the film by scoring the bottom of the glass slide. The samples were sputter coated with a about 9 nm thick film from an Au/Pd target (Denton Desk IV Sputter Coater) to avoid charging artifacts.

### Acoustic Exfoliation of 2D Materials:

The principles of acoustic exfoliation of 2D materials have been derived from studies of acoustic technology in other fields. Since the 20^{th} century, ultrasound technology has been utilized in fields as diverse as naval navigation, medicine, food science, and industrial solids processing. Meanwhile, megahertz-frequency acoustic technology, also called megasonics, emerged in the late 1970s for use in semiconductor cleaning applications. In the decades since, megasonic cleaning has been adopted as a gentler, more effective means of removing nanoparticles from the surfaces of wafers covered with delicate nanoscale structures.

The basic process of ultrasonication and megasonication in 2D material liquid phase exfoliation (LPE) is as follows. Acoustic waves are produced by piezoelectric transducers and propagate through an acoustic medium. In bath sonication, the acoustic medium is primarily water and secondarily the exfoliation solvent that is contained in a vessel; in tip sonication, the medium is simply the exfoliation solvent. As the acoustic wave travels, the pressure in the medium changes as a function of time and space. Bubbles grow in regions of negative pressure and shrink or collapse in regions of high pressure; this process is called cavitation. On average, smaller bubbles are produced at higher frequencies. Furthermore, acoustic streaming, or fluid flow induced by acoustic waves, occurs in the medium. While the nominal difference between ultrasonics and megasonics is the range of excitation frequencies—ultrasound is defined as acoustic frequencies >18 kHz, while megasonic frequencies are >350 kHz—the dominant microscale and nanoscale processes in these two regimes are markedly different.

In ultrasonication, the bubbles that form are primarily composed of vapor that evolves when the acoustic liquid is ruptured under negative pressure. During high pressure cycles, a fraction of these bubbles collapses violently and rapidly, releasing large amounts of energy, in a process known as inertial cavitation. This shockwave of energy facilitates 2D material exfoliation through mechanisms such as delamination, fragmentation, compressive stress, and shearing. Indeed, experiments with inertial cavitation generated by a tip sonotrode in the presence of a graphite crystal have shown the production of tensile stresses of 3-7 MPa, which is sufficient to overcome interlayer van der Waals forces. Acoustic streaming in ultrasonication primarily involves microjetting, in which bubble implosions generate a high-velocity jet of solvent that can plastically deform the sample surface and create pits. While some researchers have hypothesized that microjetting plays a vital role in 2D material exfoliation, recent in situ visualization experiments have not observed significant microjetting during exfoliation; rather, shockwaves induced by inertial cavitation were observed to be the primary exfoliation mechanism.

In megasonication, cavitation bubbles are primarily composed of gas. Under the influence of the acoustic field, these bubbles may coalesce, dissolve, or float out of the acoustic medium. Stable cavitation is achieved when a bubble has a minimum radius and can grow through a rectified diffusion process. Similarly to the case of ultrasonication, while acoustic streaming was long theorized to play a crucial role in megasonic cleaning, in situ visualization of this process reveals that stable oscillating bubbles are responsible for detaching nanoparticles from the surface of a substrate. Moreover, in situ visualization of stable cavitation in the presence of a graphite flake shows that pressure oscillations induce delamination from the edge of the flake. Therefore, maximizing stable cavitation through strategies such as optimizing acoustic pulse parameters, adding surfactants to the acoustic medium, or inducing liquid atomization is critical for applications in megasonic cleaning, and analogously in megasonic exfoliation. It is also valuable to note that the acoustic boundary layer decreases with increasing frequencies, causing higher viscous stresses at a substrate surface (e.g., the nanosheet surfaces). Furthermore, long range acoustic streaming, called Eckart streaming, can separate delaminated nanosheets, preventing reaggregation.

The majority of acoustic-based exfoliation research has focused on bath ultrasonication and horn tip sonication, where sonication parameters such as power, time, and temperature have been explored. Meanwhile, interest in megasonic exfoliation techniques has developed over the last five years. Several studies have demonstrated megasonic exfoliation-on-chip technology that applies about 10-20 MHz acoustic waves to a small volume (≈10 s μL) of 2D material powder dispersed in water, inducing exfoliation through acoustic streaming or liquid atomization mechanisms. Telkhozhayeva et al. reported that larger, thinner 2D nanosheets can be exfoliated by increasing the acoustic frequency, although the maximum frequency studied was only 80 kHz. Kuo et al. reported similar results by using megasonic atomization at 1.65 MHz to exfoliate large-area MoS₂ nanosheets down to the monolayer limit. These promising examples motivate more exploratory work for optimizing megasonic exfoliation conditions as well as finding the best applications for megasonically exfoliated 2D materials.

### Results and Discussions

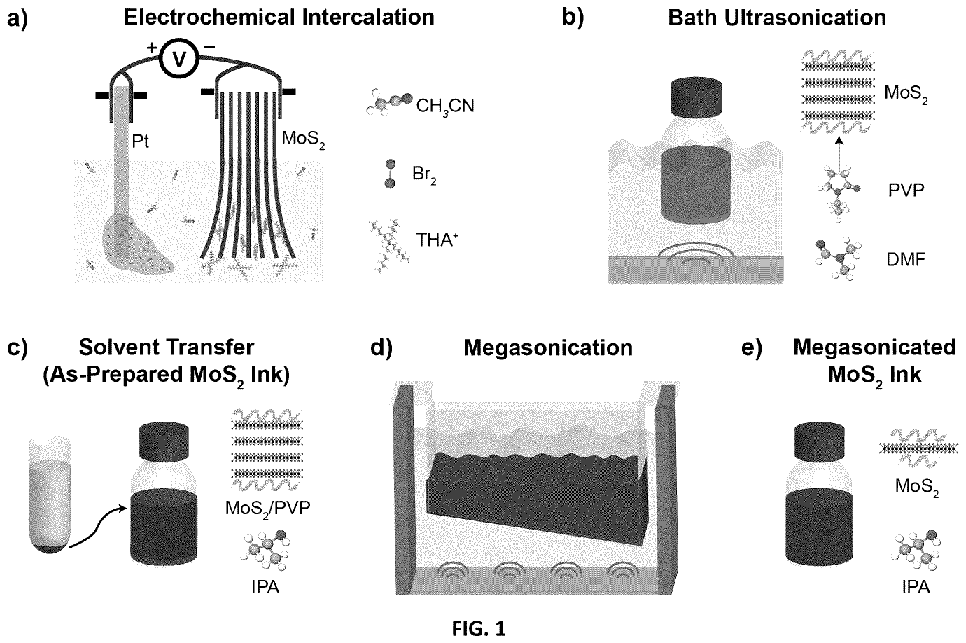

FIG. 1 provides a schematic representation of the megasonicated MoS₂ ink preparation. The ink production process begins with electrochemical intercalation (panel (a) of FIG. 1), for which an electrochemical cell was constructed with an MoS₂ crystal as the working electrode and platinum foil as the counter electrode. The electrolyte includes tetraheptylammonium bromide (THAB) salt dissolved in acetonitrile. A bias of −10 V is applied across the cell to drive THA⁺ cations to intercalate between the MoS₂ crystal layers. The intercalated MoS₂ crystals are then exfoliated by traditional bath sonication at 40 kHz (panel (b) of FIG. 1) in 0.2 M polyvinylpyrrolidone (PVP) dissolved in dimethylformamide (DMF). Although intercalating multiple MoS₂ crystals can be time-consuming, this process can be scaled up by intercalating large pellets of pressed MoS₂ powder. Next, solvent transfer via centrifugation (panel (c) of FIG. 1) is utilized to disperse the MoS₂ nanosheets in IPA while removing excess PVP and crashing out poorly exfoliated MoS₂. The resulting MoS₂ ink following this primary exfoliation step is brown in color and is labeled as-prepared MoS₂ (AP-MoS₂) throughout this study.

Following primary exfoliation, the AP-MoS₂ ink is subjected to a secondary megasonic exfoliation step. Previously, we disclosed secondary exfoliation of MoS₂ through megasonication within the atomization chamber of an Optomec AJ200 aerosol jet printer (AJP), in PCT Patent Application No. PCT/US2023/022664, which is incorporated herein in their entireties by reference. The AJP has a piezoelectric transducer that outputs a power of about 30 W/in² at 1.65 MHz to aerosolize approximately 1.5 mL volume of ink. To overcome this small volume limitation and decouple megasonication from the AJP, we instead employed a PCT Systems 0.95 MHz bath megasonicator with a power output of 36 W/in² (PCT Systems Inc., San Jose, CA 95131). This megasonicator is typically used for cleaning semiconductor wafers, but it was adapted for megasonication of MoS₂ inks by installing a quartz liner tank with a minimum fill volume of about 60 mL inside the water bath (panel (d) of FIG. 1 and panel (a) of FIG. 6). The quartz liner was fabricated by PCT Systems to allow maximum coupling of acoustic energy from the water bath to the ink in the liner tank. Alternatively, for megasonication of smaller volumes, the AP-MoS₂ ink was injected into a heat-sealed plastic pouch that was thin enough to transmit the acoustic energy through the membrane (panel (b) of FIG. 6). Utilizing the heat-sealed plastic pouch, we investigated whether megasonication could replace ultrasonication as the primary exfoliation step; however, as characterized through optical absorbance spectroscopy (data not shown), this processing change resulted in a lower concentration of exfoliated multilayer MoS₂ compared to primary ultrasonication, and no monolayer MoS₂ exciton absorbance peak was observed. Ultimately, the multi-step procedure as depicted in FIG. 1 uniquely enables the scalable preparation of large volumes of megasonicated MoS₂ (MS-MoS₂) ink (panel (e) of FIG. 1).

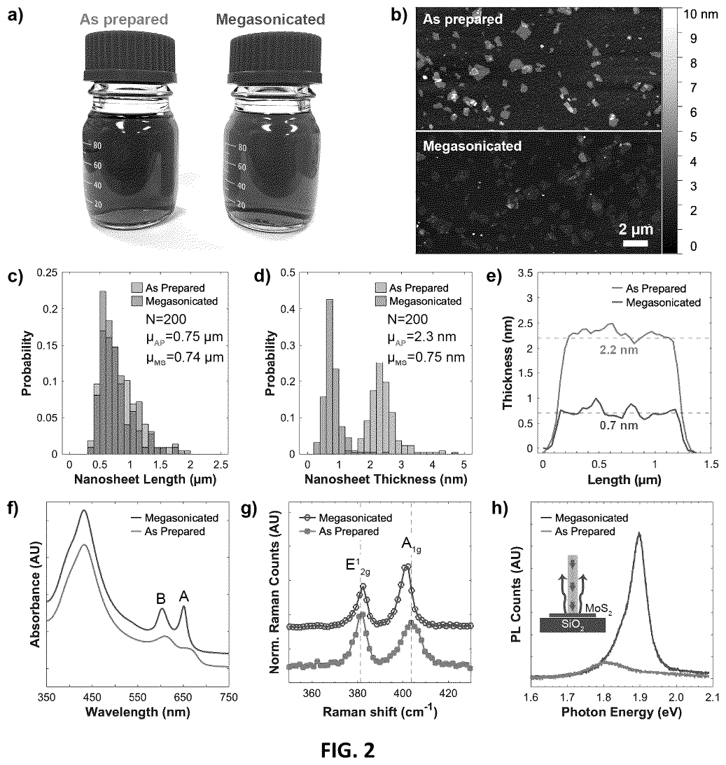

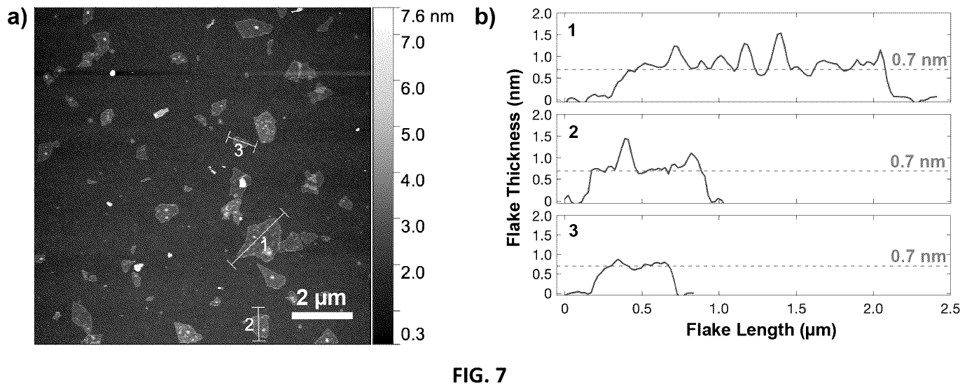

After megasonication, the MS-MoS₂ ink is a brighter green color than the AP-MoS₂ ink (panel (a) of FIG. 2), providing a visual indication of megasonic exfoliation. Quantitative verification of the efficacy of the 0.95 MHz bath megasonicator for inducing megasonic exfoliation was obtained through atomic force microscopy (AFM). To prepare samples for AFM analysis, an aliquot of each batch of ink was diluted with IPA, dropcasted on 300-nm-thick SiO₂/Si substrates, and then annealed in a tube furnace at 220° C. for 1 hour to remove residual polymer and solvent from the nanosheet surfaces. AFM topographical imaging (panel (b) of FIG. 2 and FIG. 7) reveals that the MS-MoS₂ nanosheets are significantly thinner than the AP-MoS₂ nanosheets. Extraction of nanosheet lateral sizes from AFM line scans (N=200 for each sample) yielded nanosheet length distributions for the AP-MoS₂ and MS-MoS₂ samples with similar log-normal mean lengths of 0.75 μm and 0.74 μm, respectively (panel (c) of FIG. 2). On the other hand, the nanosheet thickness distributions show that the MS-MoS₂ nanosheets are significantly thinner than the AP-MoS₂nanosheets with respective log-normal mean thicknesses of 0.75 nm and 2.3 nm (panels (d)-(e) of FIG. 2). Since monolayer MoS₂ typically appears to be approximately 0.7 nm thick in AFM measurements, the AFM results here correspond to average megasonication-induced nanosheet thinning from about 3 layers to monolayer, confirming that our scaled-up megasonication process produces a large population of monolayer MoS₂ nanosheets.

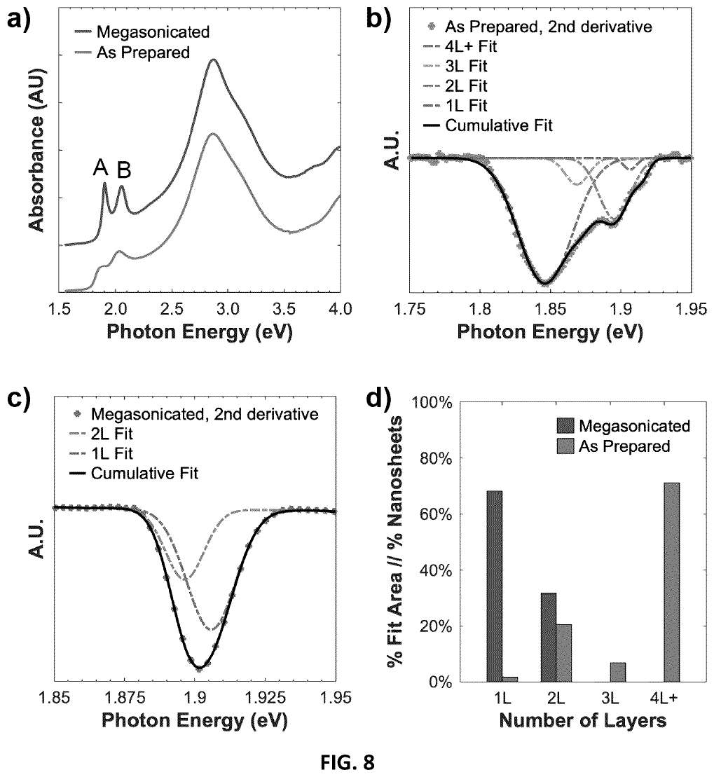

A variety of spectroscopic techniques were subsequently applied to further characterize the physical properties of the MS-MoS₂ ink and nanosheets. For example, optical absorbance spectroscopy reveals that the A and B exciton peaks for MS-MoS₂ are blue-shifted and narrower compared to those of AP-MoS₂ (panel (f) of FIG. 2). In particular, the A exciton peak shifts from about 675 nm to about 650 nm, which is consistent with previous reports of monolayer MoS₂. The optical absorbance spectra also allow the fraction of monolayer MoS₂ nanosheets to be estimated using a protocol devised by Backes et al. Specifically, the A exciton absorbance contributions are extracted from various thickness populations by fitting the second derivative of the optical absorbance spectra as a function of photon energy with Lorentzian curves (panels (a)-(c) of FIG. 8). Accordingly, we determined that the monolayer fraction significantly increases from 2% in the AP-MoS₂ ink to 68% in the MS-MoS₂ ink (panel (d) of FIG. 8).

Raman and photoluminescence (PL) spectroscopy were also performed on isolated AP-MoS₂ and MS-MoS₂ nanosheets that were dropcasted onto SiO₂/Si substrates without additional processing (a schematic is provided in the inset of panel (h) of FIG. 2). Representative Raman spectra of both samples (panel (g) of FIG. 2) show the characteristic in-plane (E¹_{2g}) and out-of-plane (A_{1g}) vibrational modes, confirming that the MoS₂ nanosheets maintain high crystallinity after megasonication. Furthermore, the distance between the E¹_{2g} and A_{1g} peaks decreases from 22.5 cm⁻¹ for AP-MoS₂ to 19.5 cm⁻¹ for MS-MoS₂, which is consistent with megasonication decreasing the nanosheet thickness down to the monolayer limit. The PL spectra in panel (h) of FIG. 2 further reflect the differences between multilayer AP-MoS₂ nanosheets and monolayer MS-MoS₂ nanosheets. First, the PL intensity of AP-MoS₂ is significantly lower than that of MS-MoS₂ because the PL quantum yield (QY) significantly decreases with increasing MoS₂ nanosheet thickness. Second, the AP-MoS₂ A exciton PL peak is centered at about 1.8 eV, which is indicative of a trion-dominated resonance that is commonly observed in the PL of multilayer MoS₂ nanosheets at room temperature. Third, the spectral shape of the MS-MoS₂ PL strongly resembles that of a mechanically exfoliated MoS₂monolayer. The MS-MoS₂ PL spectral peak position at 1.90 eV further reflects the A exciton direct bandgap transition at the K point of the Brillouin zone. In addition, a trion resonance peaked at about 1.85 eV contributes to the MS-MoS₂ PL, as has been previously reported for monolayer MoS₂. Interestingly, the B exciton peak is not observed in either the AP-MoS₂ or MS-MoS₂ PL spectra. This result can be attributed to the high structural quality of the MoS₂ nanosheets in both samples, as a low B-to-A exciton ratio indicates low defect concentration. Notably, the structural and optical properties of MS-MoS₂ monolayers agree well with those of highest quality mechanically exfoliated MoS₂ monolayers utilized in electroluminescent devices and field-effect transistors, which possess a Raman interpeak distance of about 20 cm⁻¹ as well as direct bandgap PL spectra.

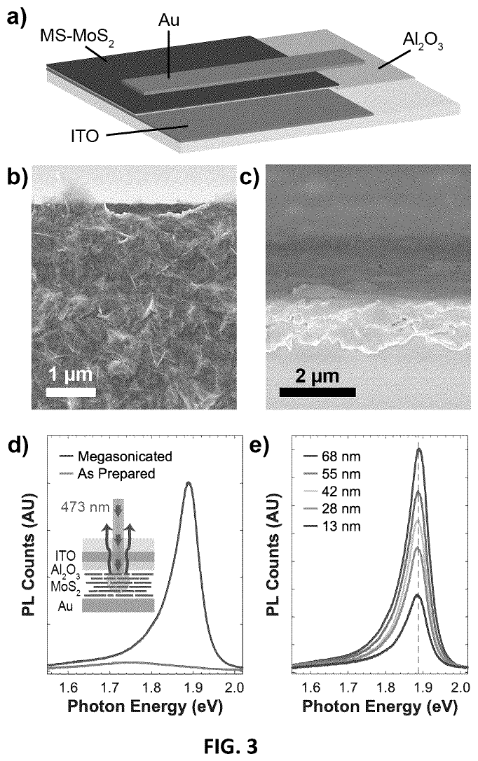

Having confirmed the superlative optoelectronic properties of MS-MoS₂ nanosheets, the MS-MoS₂ inks were used to fabricate vertical MSIM devices, which were designed to achieve EL through oscillatory bipolar carrier injection from the metal source contact into the semiconducting MoS₂ film upon application of an alternating current (AC) bias to the gate contact (panel (a) of FIG. 3). Indium tin oxide (ITO) coated on a glass substrate was utilized as the gate electrode since its optical transparency enables detection of light emission. Atomic layer deposition (ALD) was then used to grow a 60-nm-thick Al₂O₃ gate dielectric film on the ITO. Dropcasting was selected as an efficient method of fabricating large-area MoS₂ films without losing excess ink, as is unavoidable in other solution-based deposition techniques such as spin coating. The MS-MoS₂ ink was diluted to approximately 0.33 mg/mL in IPA as verified by optical absorbance spectroscopy (based on an extinction coefficient of 1987 L g⁻¹ m⁻¹ at 525 nm), after which 20% H₂O was added to the ink to enable dropcasting of uniform percolating MS-MoS₂ films at 60° C. with negligible coffee ring effects (panel (a) of FIG. 9). Films of various thicknesses were realized by dropcasting multiple layers of MS-MoS₂ ink (panel (a) of FIG. 9). Finally, source contacts were deposited by evaporating 100-nm-thick Au on top of the MS-MoS₂ film through a stainless-steel shadow mask to complete the MSIM device geometry.

Top-down and cross-sectional scanning electron microscopy (SEM) imaging of a 100-nm-thick dropcasted MS-MoS₂ film confirmed a percolating and dense nanosheet network (panels (a)-(c) of FIG. 3). Four-point-probe electrical measurements revealed a film conductivity of 0.06 S/m±0.04 S/m, which is notable since the film was not subjected to any additional annealing steps. While this conductivity is sufficient for achieving EL in the vertical MSIM devices as will be discussed below, it is likely that even higher film conductivities can be achieved by controlled annealing treatments that have been shown to enhance electrical conductivity in inkjet-printed films derived from electrochemically exfoliated MoS₂.

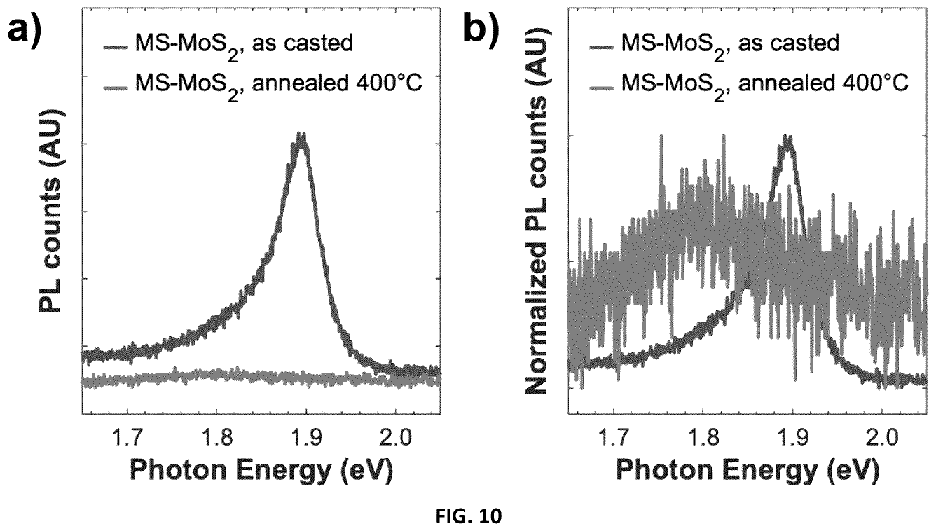

The optical properties of the MoS₂ films in the MSIM geometry were characterized using photoluminescence spectroscopy by focusing the 473 nm excitation laser through the glass/ITO substrate at the MoS₂-alumina interface (measurement schematic is provided in the inset of panel (d) of FIG. 3). AP-MoS₂ and MS-MoS₂ films (thickness about 70 nm) exhibit similar PL spectra as the respective isolated nanosheets (panel (d) of FIG. 3 and panel (h) of FIG. 2). Specifically, the AP-MoS₂ film shows weak PL that is peaked at roughly 1.75 eV due to a low fraction of monolayers, whereas the monolayer-rich MS-MoS₂ film shows bright PL that is peaked at 1.89 eV. Furthermore, the PL intensity of the MS-MoS₂ films increases with increasing film thickness while the PL peak remains at about 1.89 eV (panel (e) of FIG. 3). This trend contrasts what was reported for thin films of lithium-exfoliated MoS₂ monolayers, in which PL quenching and PL red shifting was observed as a function of increasing film thickness up to about 10 nm. These PL data indicate that individual MoS₂ monolayer nanosheets retain their direct-bandgap character in a composite film independently of film thickness, likely due to the residual PVP coating on the nanosheet surfaces that restricts strong electronic interactions between the nanosheets. To test this hypothesis, a MS-MoS₂ EL device was annealed in an Ar tube furnace at 400° C. for 30 min to completely pyrolyze the PVP coating. Subsequent characterization revealed that the PL intensity of the annealed MS-MoS₂ nanosheet film was substantially degraded (panel (a) of FIG. 10). Furthermore, a weak PL peak was observed for the annealed MS-MoS₂ at around 1.80 eV (panel (b) of FIG. 10), resembling the PL spectral shape of an AP-MoS₂ nanosheet. Thus, the PVP coating plays a critical role in maintaining the monolayer direct-bandgap optical properties of MS-MoS₂ in solution-deposited films.

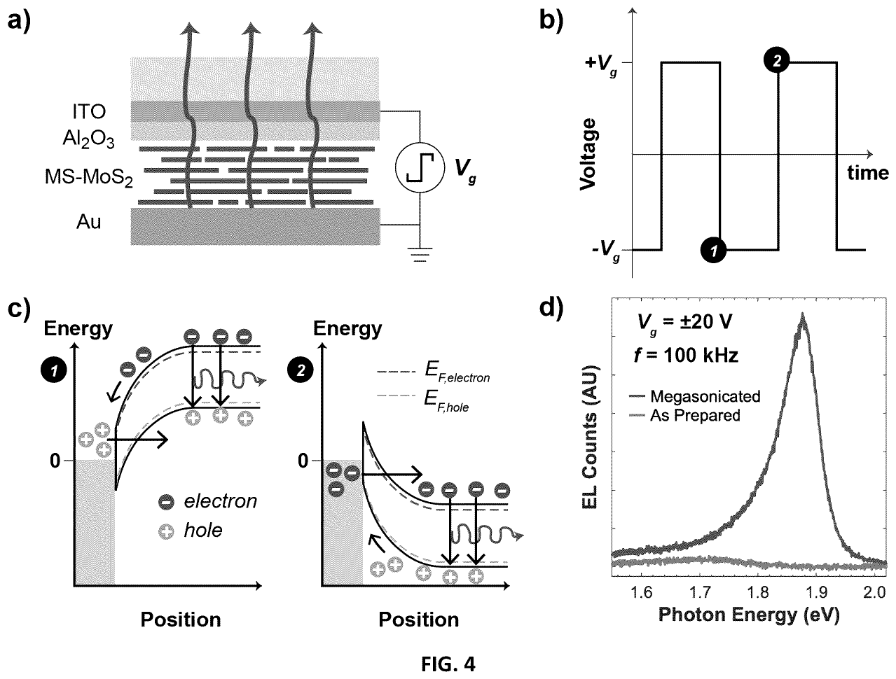

For electroluminescence measurements, light emission from the MSIM devices were detected through the ITO/glass substrate (see measurement schematic in panel (a) of FIG. 4). A waveform generator connected to a high bandwidth (1 MHz) voltage amplifier was used to apply a bipolar square wave signal V_{g} to the ITO electrode (gate) while the bottom Au electrode (source) was grounded (panel (b) of FIG. 4). During device operation, holes are injected into the MoS₂ film at negative biases, whereas electrons are injected at positive biases. When the voltage polarity is reversed, injected carriers from the Au source contact radiatively recombine with a fraction of oppositely charged carriers that remain in the semiconducting layer (panel (c) of FIG. 4). The square wave was centered about V_{g}=0 V with amplitudes in the range ±5 to ±25 V and frequencies (f) in the range of 1 to 400 kHz. Voltage amplitudes and frequencies beyond this range led to rapid device degradation including shorting due to dielectric breakdown of the alumina gate dielectric. Panel (d) of FIG. 4 compares the EL responses of about 70-nm-thick AP-MoS₂ and MS-MoS₂ films while applying a square wave with V_{g}=±20 V and f=100 kHz. The AP-MoS₂ film EL is peaked at about 1.75 eV with an intensity significantly lower than the MS-MoS₂ film EL, which is attributed to the lower QY of the thicker AP-MoS₂ nanosheets. In contrast, the MS-MoS₂ EL is peaked at about 1.88 eV, which indicates that EL is emitted from a similar excitonic state as the MS-MoS₂ PL. These MS-MoS₂ EL results underscore that the electroluminescent properties of megasonicated MoS₂ closely resemble mechanically exfoliated and CVD-grown MoS₂ monolayers.

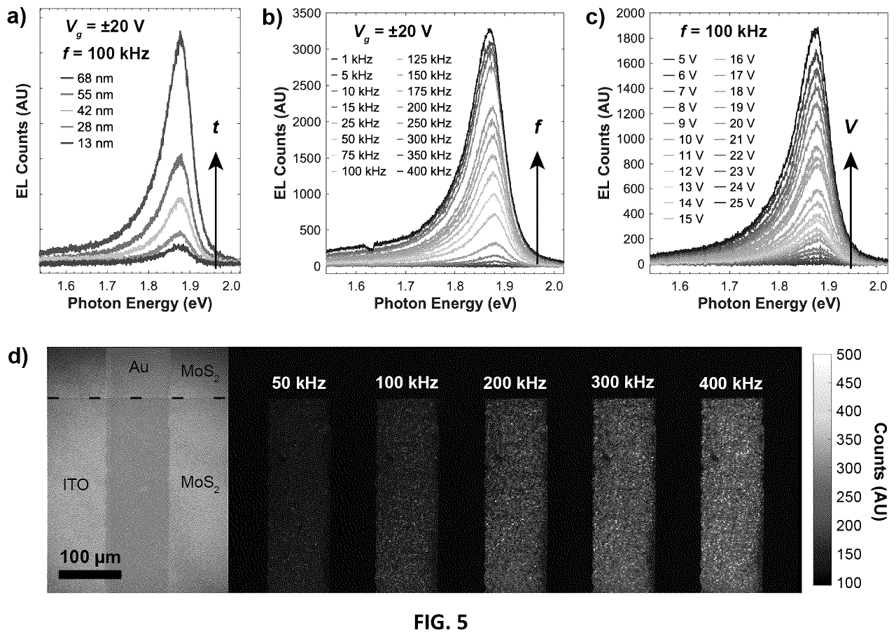

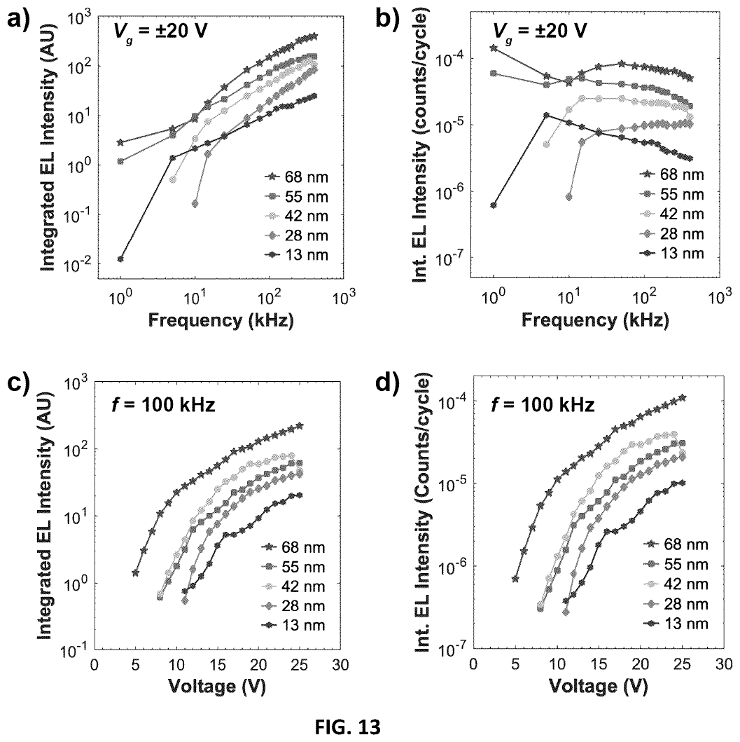

The electroluminescence of MS-MoS₂ MSIM devices was subsequently studied as a function of film thickness and square wave voltage parameters. As was observed with PL, the EL intensity increases with MS-MoS₂ film thickness (panel (a) of FIG. 5). In thin films, the EL intensity is expected to depend on both the optical absorption length and spatial extent of band bending from the Au source contact, which is a function of the MoS₂ film thickness, effective dielectric constant, morphology, and carrier mobility. For MS-MoS₂ thin films, the net effect is increasing EL with increasing film thickness up to several tens of nanometers in thickness, which enables significantly higher EL intensity than achievable with mechanically exfoliated or CVD-grown MoS₂ monolayers. In addition to film thickness, the EL intensity can be modulated by the square wave voltage parameters. Working with a about 70-nm-thick MS-MoS₂ nanosheet film, EL spectra were acquired as function of square wave frequency at a fixed amplitude V_{g}=±20 V (panel (b) of FIG. 5) and as a function of square wave amplitude at a fixed frequency f=100 kHz (panel (c) of FIG. 5). These measurements reveal that the EL intensity can be tuned over three orders of magnitude. As expected, the integrated EL intensity increases linearly with frequency due to an increased number of voltage transitions per unit time (panel (a) of FIG. 13). However, the applied waveform becomes distorted as the frequency approaches the voltage amplifier bandwidth (1 MHz), resulting in EL intensity roll-off due to the maximum V_{g} being up to 20% lower than the programmed V_{g} (panel (b) of FIG. 13) in addition to the possibility that the period of the square wave approaches the time required for effective carrier injection and transport into the depth of the film. The integrated EL intensity also increases as a function of V_{g} above the turn-on voltage (panels (c)-(d) of FIG. 13). An exponential V_{g} dependence is observed in the sub-threshold regime, which then transitions into a linear dependence as the Fermi level begins to enter the band extrema. This dependence of the EL intensity on the square wave voltage amplitude is consistent with previous MSIM device reports.

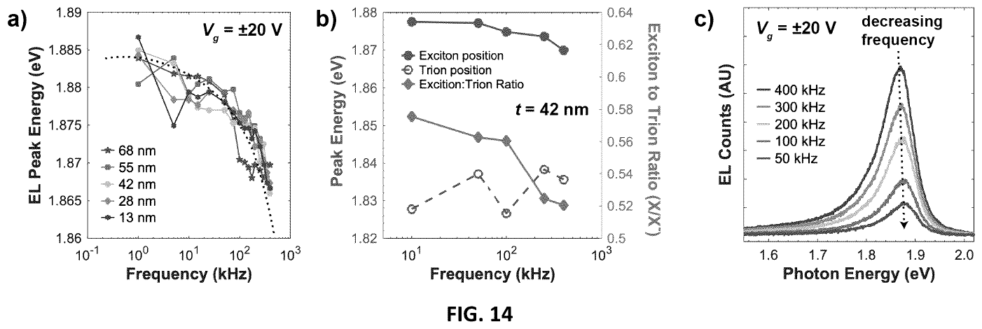

The MS-MoS₂ film EL spectra red shift slightly with increasing frequency and voltage amplitude (panel (a) of FIG. 14). This red shift may be attributed to trapped electrons in the film or Joule heating in the device. Nanosheet films are known to be susceptible to Joule heating at high biases due to energy concentration at atomically sharp nanosheet edges, with the resulting elevated temperature affecting charge transport in the film. Moreover, the displacement current in the metal electrode lines could further contribute to Joule heating in these devices. It is important to note that measuring EL with decreasing frequency from 400 kHz to 50 kHz results in a blue shifting of the EL peaks (panel (c) of FIG. 14), indicating that any charge trapping or heating effects are reversible.

Finally, a high-sensitivity CMOS camera was utilized for spatial mapping of the light emission from the vertical MSIM devices. The MS-MoS₂ film shows uniform EL over the entire 100 μm×300 μm active device region between the Au source and ITO gate electrodes, with the integrated EL intensity increasing with frequency (panel (d) of FIG. 5). Notably, previous reports of MSIM devices based on 2D materials have only demonstrated spatially localized EL within a Debye length of the source contacts. In those previous studies, the spatial uniformity was enhanced by fabricating strategically-spaced windows in the source contact or by utilizing a porous carbon nanotube network to overcome low mobility in the emitter film. In contrast, the emission area in our MSIM devices is directly determined by the patterned electrodes due to the vertical device architecture and sufficiently conductive MS-MoS₂ films with monolayer properties. The negligible EL emission beyond the edges of the source contact can be attributed to highly localized band bending directly above the electrode. The ability to spatially localize EL simply via electrode patterning suggests that these MS-MoS₂ vertical MSIM devices can be used as pixels in miniaturized light sources such as micro light emitting diodes (micro-LEDs).

### CONCLUSIONS

In summary, we have developed a megasonically exfoliated, monolayer-rich MoS₂ nanosheet ink that can be used to fabricate electroluminescent MoS₂ nanosheet films. Even at thicknesses approaching 100 nm, these MS-MoS₂ films possess PL properties comparable to mechanically exfoliated or CVD-grown MoS₂ monolayers, revealing that the MS-MoS₂ films preserve the direct bandgap properties of their constituent monolayer nanosheets. These MS-MoS₂ films have also been integrated into vertical MSIM devices, where the resulting EL can be tuned by orders of magnitude by varying the frequency and amplitude of the driving square wave voltage. In addition, the vertical MSIM device architecture provides a means for patterning the EL emission in a manner suitable for applications in display technologies. Since the EL emission is normal to patterned contacts, this MSIM device architecture is amenable to large-area additive manufacturing by sequentially printing the MS-MoS₂ ink, dielectric layer, and electrodes. Overall, this work establishes a scalable, solution-based platform for incorporating optoelectronically active monolayer TMD nanosheets into printed electronics, sensors, and related applications.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described to explain the principles of the invention and their practical application to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

Some references, which may include patents, patent applications, and various publications, are cited and discussed in the description of this invention. The citation and/or discussion of such references is provided merely to clarify the description of the invention and is not an admission that any such reference is “prior art” to the invention described herein. All references cited and discussed in this specification are incorporated herein by reference in their entireties and to the same extent as if each reference was individually incorporated by reference.

### LIST OF REFERENCES

[1]. Wang, J.; Verzhbitskiy, I.; Eda, G. Electroluminescent Devices Based on 2D Semiconducting Transition Metal Dichalcogenides. Adv. Mater. 2018, 30, 1802687. https://doi.org/10.1002/adma.201802687.
[2]. Fu, Q.; Hu, Z.; Zhou, M.; Lu, J.; Ni, Z. Excitonic Emission in Atomically Thin Electroluminescent Devices. Laser Photonics Rev. 2021, 15, 2000587. https://doi.org/10.1002/Ipor.202000587.
[3]. Jayathilaka, W. A. D. M.; Chinnappan, A.; Tey, J. N.; Wei, J.; Ramakrishna, S. Alternative Current Electroluminescence and Flexible Light Emitting Devices. J. Mater. Chem. C 2019, 7, 5553-5572. https://doi.org/10.1039/c9tc01267b.
[4]. Howell, S. L.; Jariwala, D.; Wu, C. C.; Chen, K. S.; Sangwan, V. K.; Kang, J.; Marks, T. J.; Hersam, M. C.; Lauhon, L. J. Investigation of Band-Offsets at Monolayer-Multilayer MoS₂ Junctions by Scanning Photocurrent Microscopy. Nano Lett. 2015, 15, 2278-2284. https://doi.org/10.1021/nl504311p.
[5]. Splendiani, A.; Sun, L.; Zhang, Y.; Li, T.; Kim, J.; Chim, C. Y.; Galli, G.; Wang, F.

Emerging Photoluminescence in Monolayer MoS₂. Nano Lett. 2010, 10, 1271-1275. https://doi.org/10.1021/n1903868w.
[6]. Jariwala, D.; Sangwan, V. K.; Lauhon, L. J.; Marks, T. J.; Hersam, M. C. Emerging Device Applications for Semiconducting Two-Dimensional Transition Metal Dichalcogenides. ACS Nano 2014, 8, 1102-1120. https://doi.org/10.1021/nn500064s.
[7]. Steinhoff, A.; Kim, J. H.; Jahnke, F.; ROsner, M.; Kim, D. S.; Lee, C.; Han, G. H.; Jeong, M. S.; Wehling, T. O.; Gies, C. Efficient Excitonic Photoluminescence in Direct and Indirect Band Gap Monolayer MoS₂. Nano Lett. 2015, 15, 6841-6847. https://doi.org/10.1021/acs.nanolett.5b02719.
[8]. Amani, M.; Burke, R. A.; Ji, X.; Zhao, P.; Lien, D. H.; Taheri, P.; Ahn, G. H.; Kirya, D.; Ager, J. W.; Yablonovitch, E.; Kong, J.; Dubey, M.; Javey, A. High Luminescence Efficiency in MoS₂ Grown by Chemical Vapor Deposition. ACS Nano 2016, 10, 6535-6541. https://doi.org/10.1021/acsnano.6b03443.
[9]. Pospischil, A.; Furchi, M. M.; Mueller, T. Solar-Energy Conversion and Light Emission in an Atomic Monolayer p-n Diode. Nat. Nanotechnol. 2014, 9, 257-261. https://doi.org/10.1038/nnano.2014.14.
[10]. Baugher, B. W. H.; Churchill, H. O. H.; Yang, Y.; Jarillo-Herrero, P. Optoelectronic Devices Based on Electrically Tunable p-n Diodes in a Monolayer Dichalcogenide. Nat. Nanotechnol. 2014, 9, 262-267. https://doi.org/10.1038/nnano.2014.25.
[11]. Paur, M.; Molina-Mendoza, A. J.; Bratschitsch, R.; Watanabe, K.; Taniguchi, T.; Mueller, T. Electroluminescence from Multi-Particle Exciton Complexes in Transition Metal Dichalcogenide Semiconductors. Nat. Commun. 2019, 10, 1709. https://doi.org/10.1038/s41467-019-09781-y.
[12]. Utama, M. I. B.; Zeng, H.; Sadhukhan, T.; Dasgupta, A.; Gavin, S. C.; Ananth, R.; Lebedev, D.; Wang, W.; Chen, J. S.; Watanabe, K.; Taniguchi, T.; Marks, T. J.; Ma, X.; Weiss, E. A.; Schatz, G. C.; Stern, N. P.; Hersam, M. C. Chemomechanical Modification of Quantum Emission in Monolayer WSe₂. Nat. Commun. 2023, 14, 2193. https://doi.org/10.1038/s41467-023-37892-0.
[13]. Jin, X.; Hu, G.; Zhang, M.; Albrow-Owen, T.; Zheng, Z.; Hasan, T. Environmentally Stable Black Phosphorus Saturable Absorber for Ultrafast Laser. Nanophotonics 2020, 9, 2445-2449. https://doi.org/10.1515/nanoph-2019-0524.
[14]. Kuo, L.; Sangwan, V. K.; Rangnekar, S. V.; Chu, T.; Lam, D.; Zhu, Z.; Richter, L. J.; Li, R.; Szydlowska, B. M.; Downing, J. R.; Luijten, B. J.; Lauhon, L. J.; Hersam, M. C. All-Printed Ultrahigh-Responsivity MoS₂ Nanosheet Photodetectors Enabled by Megasonic Exfoliation. Adv. Mater. 2022, 34, 2203772. https://doi.org/10.1002/adma.202203772.
[15]. Seo, J. W. T.; Zhu, J.; Sangwan, V. K.; Secor, E. B.; Wallace, S. G.; Hersam, M. C. Fully Inkjet-Printed, Mechanically Flexible MoS₂ Nanosheet Photodetectors. ACS Appl. Mater. Interfaces 2019, 11, 5675-5681. https://doi.org/10.1021/acsami.8b19817.
[16]. Radisavljevic, B.; Radenovic, A.; Brivio, J.; Giacometti, V.; Kis, A. Single-Layer MoS₂ Transistors. Nat. Nanotechnol. 2011, 6, 147-150. https://doi.org/10.1038/nnano.2010.279.
[17]. Sebastian, A.; Pendurthi, R.; Choudhury, T. H.; Redwing, J. M.; Das, S. Benchmarking Monolayer MoS₂ and WS₂ Field-Effect Transistors. Nat. Commun. 2021, 12, 693. https://doi.org/10.1038/s41467-020-20732-w.
[18]. Singh, E.; Singh, P.; Kim, K. S.; Yeom, G. Y.; Nalwa, H. S. Flexible Molybdenum Disulfide (MoS₂) Atomic Layers for Wearable Electronics and Optoelectronics. ACS Appl. Mater. Interfaces 2019, 11, 11061-11105. https://doi.org/10.1021/acsami.8b19859.
[19]. Sundaram, R. S.; Engel, M.; Lombardo, A.; Krupke, R.; Ferrari, A. C.; Avouris, P.; Steiner, M. Electroluminescence in Single Layer MoS₂. Nano Lett. 2013, 13, 1416-1421.
[20]. Cheng, R.; Li, D.; Zhou, H.; Wang, C.; Yin, A.; Jiang, S.; Liu, Y.; Chen, Y.; Huang, Y.; Duan, X. Electroluminescence and Photocurrent Generation from Atomically Sharp WSe₂/MoS₂ Heterojunction p-n Diodes. Nano Lett. 2014, 14, 5590-5597. https://doi.org/10.1021/nl502075n.
[21]. Henck, H.; Mauro, D.; Domaretskiy, D.; Philippi, M.; Memaran, S.; Zheng, W.; Lu, Z.; Shcherbakov, D.; Lau, C. N.; Smirnov, D.; Balicas, L.; Watanabe, K.; Taniguchi, T.; Fal'ko, V. I.; Gutierrez-Lezama, I.; Ubrig, N.; Morpurgo, A. F. Light Sources with Bias Tunable Spectrum Based on van der Waals Interface Transistors. Nat. Commun. 2022, 13, 3917. https://doi.org/10.1038/s41467-022-31605-9.
[22]. Withers, F.; Del Pozo-Zamudio, O.; Mishchenko, A.; Rooney, A. P.; Gholinia, A.; Watanabe, K.; Taniguchi, T.; Haigh, S. J.; Geim, A. K.; Tartakovskii, A. I.; Novoselov, K. S. Light-Emitting Diodes by Band-Structure Engineering in van der Waals Heterostructures. Nat. Mater. 2015, 14, 301-306. https://doi.org/10.1038/nmat4205.
[23]. Clark, G.; Schaibley, J. R.; Ross, J.; Taniguchi, T.; Watanabe, K.; Hendrickson, J. R.; Mou, S.; Yao, W.; Xu, X. Single Defect Light-Emitting Diode in a van der Waals Heterostructure. Nano Lett. 2016, 16, 3944-3948. https://doi.org/10.1021/acs.nanolett.6b01580.
[24]. Lien, D. H.; Amani, M.; Desai, S. B.; Ahn, G. H.; Han, K.; He, J. H.; Ager, J. W.; Wu, M. C.; Javey, A. Large-Area and Bright Pulsed Electroluminescence in Monolayer Semiconductors. Nat. Commun. 2018, 9, 1229. https://doi.org/10.1038/s41467-018-03218-8.
[25]. Zhao, Y.; Wang, V.; Lien, D. H.; Javey, A. A Generic Electroluminescent Device for Emission from Infrared to Ultraviolet Wavelengths. Nat. Electron. 2020, 3, 612-621. https://doi.org/10.1038/s41928-020-0459-z.
[26]. Wang, V.; Zhao, Y.; Javey, A. Performance Limits of an Alternating Current Electroluminescent Device. Adv. Mater. 2021, 33, 2005635. https://doi.org/10.1002/adma.202005635.
[27]. Ye, Y.; Ye, Z.; Gharghi, M.; Zhu, H.; Zhao, M.; Wang, Y.; Yin, X.; Zhang, X. Exciton-Dominant Electroluminescence from a Diode of Monolayer MoS₂. Appl. Phys. Lett. 2014, 104, 193508. https://doi.org/10.1063/1.4875959.
[28]. Palacios-Berraquero, C.; Barbone, M.; Kara, D. M.; Chen, X.; Goykhman, I.; Yoon, D.; Ott, A. K.; Beitner, J.; Watanabe, K.; Taniguchi, T.; Ferrari, A. C.; Atattire, M.

Atomically Thin Quantum Light-Emitting Diodes. Nat. Commun. 2016, 7, 12978. https://doi.org/10.1038/ncommsl2978.
[29]. Dobusch, L.; Schuler, S.; Perebeinos, V.; Mueller, T. Thermal Light Emission from Monolayer MoS₂. Adv. Mater. 2017, 29, 1701304. https://doi.org/10.1002/adma.201701304.
[30]. Wang, S.; Wang, J.; Zhao, W.; Giustiniano, F.; Chu, L.; Verzhbitskiy, I.; Zhou Yong, J.; Eda, G. Efficient Carrier-to-Exciton Conversion in Field Emission Tunnel Diodes Based on MIS-Type van der Waals Heterostack. Nano Lett. 2017, 17, 5156-5162. https://doi.org/10.1021/acs.nanolett.7b02617.
[31]. Han, K.; Ahn, G. H.; Cho, J.; Lien, D. H.; Amani, M.; Desai, S. B.; Zhang, G.; Kim, H.; Gupta, N.; Javey, A.; Wu, M. C. Bright Electroluminescence in Ambient Conditions from WSe₂p-n Diodes Using Pulsed Injection. Appl. Phys. Lett. 2019, 115, 011103. https://doi.org/10.1063/1.5100306.
[32]. Wang, J.; Lin, F.; Verzhbitskiy, I.; Watanabe, K.; Taniguchi, T.; Martin, J.; Eda, G.

Polarity Tunable Trionic Electroluminescence in Monolayer WSe₂. Nano Lett. 2019, 19, 7470-7475. https://doi.org/10.1021/acs.nanolett.9b03215.
[33]. Andrzejewski, D.; Hopmann, E.; John, M.; Kiimmell, T.; Bacher, G. WS₂ Monolayer-Based Light-Emitting Devices in a Vertical p-n Architecture. Nanoscale 2019, 11, 8372-8379. https://doi.org/10.1039/c9nr01573f.
[34]. Wang, J.; Rousseau, A.; Yang, M.; Low, T.; Francoeur, S.; K6na-Cohen, S. Mid-Infrared Polarized Emission from Black Phosphorus Light-Emitting Diodes. Nano Lett. 2020, 20, 3651-3655. https://doi.org/10.1021/acs.nanolett.0c00581.
[35]. Kwak, D.; Paur, M.; Watanabe, K.; Taniguchi, T.; Mueller, T. High-Speed Electroluminescence Modulation in Monolayer WS₂. Adv. Mater. Technol. 2022, 7, 2100915. https://doi.org/10.1002/admt.202100915.
[36]. Zhu, Y.; Wang, B.; Li, Z.; Zhang, J.; Tang, Y.; Torres, J. F.; Lipinski, W.; Fu, L.; Lu, Y.

A High-Efficiency Wavelength-Tunable Monolayer LED with Hybrid Continuous-Pulsed Injection. Adv. Mater. 2021, 33, 2101375. https://doi.org/10.1002/adma.202101375.
[37]. Puchert, R. P.; Hofmann, F. J.; Angerer, H. S.; Vogelsang, J.; Bange, S.; Lupton, J. M. Linearly Polarized Electroluminescence from MoS₂ Monolayers Deposited on Metal Nanoparticles: Toward Tunable Room-Temperature Single-Photon Sources. Small 2021, 17, 2006425. https://doi.org/10.1002/sm11.202006425.
[38]. Cho, J.; Amani, M.; Lien, D. H.; Kim, H.; Yeh, M.; Wang, V.; Tan, C.; Javey, A. Centimeter-Scale and Visible Wavelength Monolayer Light-Emitting Devices. Adv. Funct. Mater. 2020, 30, 1907941. https://doi.org/10.1002/adfm.201907941.
[39]. Andrzejewski, D.; Oliver, R.; Beckmann, Y.; Grundmann, A.; Heuken, M.; Kalisch, H.; Vescan, A.; Kümmell, T.; Bacher, G. Flexible Large-Area Light-Emitting Devices Based on WS₂ Monolayers. Adv. Opt. Mater. 2020, 8, 2000694. https://doi.org/10.1002/adom.202000694.
[40]. Hu, G.; Kang, J.; Ng, L. W. T.; Zhu, X.; Howe, R. C. T.; Jones, C. G.; Hersam, M. C.; Hasan, T. Functional Inks and Printing of Two-Dimensional Materials. Chem. Soc. Rev. 2018, 47, 3265-3300. https://doi.org/10.1039/C8CS00084K.
[41]. Cunningham, G.; Khan, U.; Backes, C.; Hanlon, D.; McCloskey, D.; Donegan, J. F.; Coleman, J. N. Photoconductivity of Solution-Processed MoS₂ Films. J. Mater. Chem. C 2013, 1, 6899-6904. https://doi.org/10.1039/c3tc31402b.
[42]. Lee, Y.; Yang, J.; Lee, D.; Kim, Y. H.; Park, J. H.; Kim, H.; Cho, J. H. Trap-Induced Photoresponse of Solution-Synthesized MoS₂. Nanoscale 2016, 8, 9193-9200. https://doi.org/10.1039/c6nr00654j.
[43]. Yin, Z.; Zhang, X.; Cai, Y.; Chen, J.; Wong, J. I.; Tay, Y. Y.; Chai, J.; Wu, J.; Zeng, Z.; Zheng, B.; Yang, H. Y.; Zhang, H. Preparation of MoS₂—MoO₃ Hybrid Nanomaterials for Light-Emitting Diodes. Angew. Chemie—Int. Ed. 2014, 53, 12560-12565. https://doi.org/10.1002/anie.201402935.
[44]. Mukherjee, S.; Maiti, R.; Katiyar, A. K.; Das, S.; Ray, S. K. Novel Colloidal MoS₂ Quantum Dot Heterojunctions on Silicon Platforms for Multifunctional Optoelectronic Devices. Sci. Rep. 2016, 6, 29016. https://doi.org/10.1038/srep29016.
[45]. Zhang, X.; Li, W.; Ling, Z.; Zhang, Y.; Xu, J.; Wang, H.; Chen, G.; Wei, B. Facile Synthesis of Solution-Processed MoS₂ Nanosheets and Their Application in High-Performance Ultraviolet Organic Light-Emitting Diodes. J. Mater. Chem. C 2019, 7, 926-936. https://doi.org/10.1039/c8tc05370g.
[46]. Lin, Z.; Liu, Y.; Halim, U.; Ding, M.; Liu, Y.; Wang, Y.; Jia, C.; Chen, P.; Duan, X.; Wang, C.; Song, F.; Li, M.; Wan, C.; Huang, Y.; Duan, X. Solution-Processable 2D Semiconductors for High-Performance Large-Area Electronics. Nature 2018, 562, 254-258. https://doi.org/10.1038/s41586-018-0574-4.
[47]. Song, O.; Rhee, D.; Kim, J.; Jeon, Y.; Mazinek, V.; S6ll, A.; Kwon, Y. A.; Cho, J. H.; Kim, Y. H.; Sofer, Z.; Kang, J. All Inkjet-Printed Electronics Based on Electrochemically Exfoliated Two-Dimensional Metal, Semiconductor, and Dielectric. npj 2D Mater. Appl. 2022, 6, 64. https://doi.org/10.1038/s41699-022-00337-1.
[48]. Kong, L.; Li, G.; Su, Q.; Zhang, X.; Liu, Z.; Liao, G.; Sun, B.; Shi, T. Inkjet-Printed, Large-Area, Flexible Photodetector Array Based on Electrochemical Exfoliated MoS₂ Film for Photoimaging. Adv. Eng. Mater. 2023, 25, 2200946. https://doi.org/10.1002/adem.202200946.
[49]. Wang, K.; Li, L.; Zhao, R.; Zhao, J.; Zhou, Z.; Wang, J.; Wang, H.; Tang, B.; Lu, C.; Lou, J.; Chen, J.; Yan, X. A Pure 2H-MoS₂ Nanosheet-Based Memristor with Low Power Consumption and Linear Multilevel Storage for Artificial Synapse Emulator. Adv. Electron. Mater. 2020, 6, 1901342. https://doi.org/10.1002/aelm.201901342.
[50]. Tang, B.; Veluri, H.; Li, Y.; Yu, Z. G.; Waqar, M.; Leong, J. F.; Sivan, M.; Zamburg, E.; Zhang, Y.-W.; Wang, J.; Thean, A. V. Y. Wafer-Scale Solution-Processed 2D Material Analog Resistive Memory Array for Memory-Based Computing. Nat. Commun. 2022, 13, 3037. https://doi.org/10.1038/s41467-022-30519-w.
[51]. Kelly, A. G.; Hallam, T.; Backes, C.; Harvey, A.; Esmaeily, A. S.; Godwin, I.; Coelho, J.; Nicolosi, V.; Lauth, J.; Kulkarni, A.; Kinge, S.; Siebbeles, L. D. A.; Duesberg, G. S.; Coleman, J. N. All-Printed Thin-Film Transistors from Networks of Liquid-Exfoliated Nanosheets. Science 2017, 356, 69-73. https://doi.org/10.1126/science.aal4062.
[52]. Varrla, E.; Backes, C.; Paton, K. R.; Harvey, A.; Gholamvand, Z.; McCauley, J.; Coleman, J. N. Large-Scale Production of Size-Controlled MoS₂ Nanosheets by Shear Exfoliation. Chem. Mater. 2015, 27, 1129-1139. https://doi.org/10.1021/cm5044864.
[53]. Kang, J.; Seo, J. W. T.; Alducin, D.; Ponce, A.; Yacaman, M. J.; Hersam, M. C. Thickness Sorting of Two-Dimensional Transition Metal Dichalcogenides via Copolymer-Assisted Density Gradient Ultracentrifugation. Nat. Commun. 2014, 5, 5478. https://doi.org/10.1038/ncomms6478.
[54]. Kang, J.; Sangwan, V. K.; Wood, J. D.; Hersam, M. C. Solution-Based Processing of Monodisperse Two-Dimensional Nanomaterials. Acc. Chem. Res. 2017, 50, 943-951. https://doi.org/10.1021/acs.accounts.6b00643.
[55]. Backes, C.; Szydlowska, B. M.; Harvey, A.; Yuan, S.; Vega-Mayoral, V.; Davies, B. R.; Zhao, P.; Hanlon, D.; Santos, E. J. G.; Katsnelson, M. I.; Blau, W. J.; Gadermaier, C.; Coleman, J. N. Production of Highly Monolayer Enriched Dispersions of Liquid-Exfoliated Nanosheets by Liquid Cascade Centrifugation. ACS Nano 2016, 10, 1589-1601. https://doi.org/10.1021/acsnano.5b07228.
[56]. Tao, H.; Zhang, Y.; Gao, Y.; Sun, Z.; Yan, C.; Texter, J. Scalable Exfoliation and Dispersion of Two-Dimensional Materials-an Update. Phys. Chem. Chem. Phys. 2017, 19, 921-960. https://doi.org/10.1039/c6cp06813h.
[57]. Brems, S.; Hauptmann, M.; Camerotto, E.; Pacco, A.; Kim, T.-G.; Xu, X.; Wostyn, K.; Mertens, P.; De Gendt, S. Nanoparticle Removal with Megasonics: A Review. ECS J. Solid State Sci. Technol. 2014, 3, N3010-N3015. https://doi.org/10.1149/2.004401jss.
[58]. Wells, R. A.; Zhang, M.; Chen, T. H.; Boureau, V.; Caretti, M.; Liu, Y.; Yum, J. H.; Johnson, H.; Kinge, S.; Radenovic, A.; Sivula, K. High Performance Semiconducting Nanosheets via a Scalable Powder-Based Electrochemical Exfoliation Technique. ACS Nano 2022, 16, 5719-5730. https://doi.org/10.1021/acsnano.1c10739.
[59]. Hatano, H.; Kanai, S. High-Frequency Ultrasonic Cleaning Tank Utilizing Oblique Incidence. IEEE Trans. Ultrason. Ferroelectr. Freq. Control 1996, 43, 531-535. https://doi.org/10.1109/58.503712.
[60]. Castellanos-Gomez, A.; Quereda, J.; Van Der Meulen, H. P.; Agräit, N.; Rubio-Bollinger, G. Spatially Resolved Optical Absorption Spectroscopy of Single- and Few-Layer MoS₂ by Hyperspectral Imaging. Nanotechnology 2016, 27, 115705. https://doi.org/10.1088/0957-4484/27/11/115705.
[61]. Backes, C.; Hanlon, D.; Szydlowska, B. M.; Harvey, A.; Smith, R. J.; Higgins, T. M.; Coleman, J. N. Preparation of Liquid-Exfoliated Transition Metal Dichalcogenide Nanosheets with Controlled Size and Thickness: A State of the Art Protocol. J. Vis. Exp. 2016, 2016, 10-13. https://doi.org/10.3791/54806.
[62]. McDevitt, N. T.; Bultman, J. E.; Zabinski, J. S. Study of Amorphous MoS₂ Films Grown by Pulsed Laser Deposition. Appl. Spectrosc. 1998, 52, 1160-1164. https://doi.org/10.1366/0003702981945165.
[63]. Li, H.; Zhang, Q.; Yap, C. C. R.; Tay, B. K.; Edwin, T. H. T.; Olivier, A.; Baillargeat, D. From Bulk to Monolayer MoS₂: Evolution of Raman Scattering. Adv. Funct. Mater. 2012, 22, 1385-1390. https://doi.org/10.1002/adfm.201102111.
[64]. Chakraborty, B.; Matte, H. S. S. R.; Sood, A. K.; Rao, C. N. R. Layer-Dependent Resonant Raman Scattering of a Few Layer MoS₂. J. Raman Spectrosc. 2013, 44, 92-96. https://doi.org/10.1002/jrs.4147.
[65]. Mak, K. F.; Lee, C.; Hone, J.; Shan, J.; Heinz, T. F. Atomically Thin MoS₂: A New Direct-Gap Semiconductor. Phys. Rev. Lett. 2010, 105, 136805. https://doi.org/10.1103/PhysRevLett.105.136805.
[66]. Pei, J.; Yang, J.; Xu, R.; Zeng, Y. H.; Myint, Y. W.; Zhang, S.; Zheng, J. C.; Qin, Q.; Wang, X.; Jiang, W.; Lu, Y. Exciton and Trion Dynamics in Bilayer MoS₂. Small 2015, 11, 6384-6390. https://doi.org/10.1002/smll.201501949.
[67]. Golovynskyi, S.; Irfan, I.; Bosi, M.; Seravalli, L.; Datsenko, O. I.; Golovynska, I.; Li, B.; Lin, D.; Qu, J. Exciton and Trion in Few-Layer MoS₂: Thickness- and Temperature-Dependent Photoluminescence. Appl. Surf Sci. 2020, 515, 146033. https://doi.org/10.1016/j.apsusc.2020.146033.
[68]. Eda, G.; Yamaguchi, H.; Voiry, D.; Fujita, T.; Chen, M.; Chhowalla, M. Photoluminescence from Chemically Exfoliated MoS₂. Nano Lett. 2011, 11, 5111-5116. https://doi.org/10.1021/n1201874w.
[69]. Mak, K. F.; He, K.; Lee, C.; Lee, G. H.; Hone, J.; Heinz, T. F.; Shan, J. Tightly Bound Trions in Monolayer MoS₂. Nat. Mater. 2013, 12, 207-211. https://doi.org/10.1038/nmat3505.
[70]. McCreary, K. M.; Hanbicki, A. T.; Sivaram, S. V.; Jonker, B. T. A- and B-Exciton Photoluminescence Intensity Ratio as a Measure of Sample Quality for Transition Metal Dichalcogenide Monolayers. APL Mater. 2018, 6, 111106. https://doi.org/10.1063/1.5053699.
[71]. Jariwala, D.; Sangwan, V. K.; Late, D. J.; Johns, J. E.; Dravid, V. P.; Marks, T. J.; Lauhon, L. J.; Hersam, M. C. Band-like Transport in High Mobility Unencapsulated Single-Layer MoS₂ Transistors. Appl. Phys. Lett. 2013, 102, 173107. https://doi.org/10.1063/1.4803920.
[72]. Ponomarev, E.; Gutiérrez-Lezama, I.; Ubrig, N.; Morpurgo, A. F. Ambipolar Light-Emitting Transistors on Chemical Vapor Deposited Monolayer MoS₂. Nano Lett. 2015, 15, 8289-8294. https://doi.org/10.1021/acs.nanolett.5b03885.
[73]. Finn, D. J.; Lotya, M.; Cunningham, G.; Smith, R. J.; McCloskey, D.; Donegan, J. F.; Coleman, J. N. Inkjet Deposition of Liquid-Exfoliated Graphene and MoS₂ Nanosheets for Printed Device Applications. J. Mater. Chem. C 2014, 2, 925-932. https://doi.org/10.1039/c3tc31993h.
[74]. Majling, J.; Bača, L.; Kozánková, J.; Kocifaj, M.; Füglein, E. Polyvinylpyrrolidone Thin Film Pyrolysis as Accessed by the Real-Time Optical Transmission Measurements. J. Therm. Anal. Calorim. 2013, 114, 417-422. https://doi.org/10.1007/s10973-013-2954-1.
[75]. Ye, Y.; Ye, Z.; Gharghi, M.; Yin, X.; Zhu, H.; Zhao, M.; Zhang, X. Exciton-Related Electroluminescence from Monolayer MoS₂. In CLEO: 2014; OSA: Washington, D.C., 2014; p STh4B.4. https://doi.org/10.1364/CLEO_SI.2014.STh4B.4.
[76]. Sangwan, V. K.; Rangnekar, S. V.; Kang, J.; Shen, J.; Lee, H. S.; Lam, D.; Shen, J.; Liu, X.; de Moraes, A. C. M.; Kuo, L.; Gu, J.; Wang, H.; Hersam, M. C. Visualizing Thermally Activated Memristive Switching in Percolating Networks of Solution-Processed 2D Semiconductors. Adv. Funct. Mater. 2021, 31, 2107385. https://doi.org/10.1002/adfm.202107385.
[77]. Uddin, S. Z.; Higashitarumizu, N.; Kim, H.; Rahman, I. K. M. R.; Javey, A. Efficiency Roll-Off Free Electroluminescence from Monolayer WSe₂. Nano Lett. 2022, 22, 5316-5321. https://doi.org/10.1021/acs.nanolett.2c01311.
[78]. Shin, J.; Kim, H.; Sundaram, S.; Jeong, J.; Park, B. I.; Chang, C. S.; Choi, J.; Kim, T.; Saravanapavanantham, M.; Lu, K.; Kim, S.; Suh, J. M.; Kim, K. S.; Song, M. K.; Liu, Y.; Qiao, K.; Kim, J. H.; Kim, Y.; Kang, J. H.; Kim, J.; Lee, D.; Lee, J.; Kim, J. S.; Lee, H. E.; Yeon, H.; Kum, H. S.; Bae, S. H.; Bulovic, V.; Yu, K. J.; Lee, K.; Chung, K.; Hong, Y. J.; Ougazzaden, A.; Kim, J. Vertical Full-Colour Micro-LEDs via 2D Materials-Based Layer Transfer. Nature 2023, 614, 81-87. https://doi.org/10.1038/s41586-022-05612-1.
[79]. Hyun, W. J.; Chaney, L. E.; Downing, J. R.; De Moraes, A. C. M.; Hersam, M. C. Printable Hexagonal Boron Nitride Ionogels. Faraday Discuss. 2021, 227, 92-104. https://doi.org/10.1039/c9fd00113a.
[80]. Mayer, A.; Shwartzman, S. Megasonic Cleaning: A New Cleaning and Drying System for Use in Semiconductor Processing. J. Electron. Mater. 1979, 8, 855-864. https://doi.org/10.1007/BF02651188.
[81]. Turner, P.; Hodnett, M.; Dorey, R.; Carey, J. D. Controlled Sonication as a Route to in situ Graphene Flake Size Control. Sci. Rep. 2019, 9, 8710. https://doi.org/10.1038/s41598-019-45059-5.
[82]. Brotchie, A.; Grieser, F.; Ashokkumar, M. Effect of Power and Frequency on Bubble-Size Distributions in Acoustic Cavitation. Phys. Rev. Lett. 2009, 102, 084302. https://doi.org/10.1103/PhysRevLett.102.084302.
[83]. Blackstone-Ney-Ultrasonics. Fundamentals of Ultrasonic & Megasonic Cleaning. Process Cleaning Magazine. Gardner Publications: Cincinnati, OH November 2009. https://www.ctgclean.com/files/wp-content/uploads/Fundamentals-of-Ultrasonics.pdf.
[84]. Malaki, M.; Maleki, A.; Varma, R. S. MXenes and Ultrasonication. J. Mater. Chem. A 2019, 7, 10843-10857. https://doi.org/10.1039/c9ta01850f.
[85]. Qin, L.; Maciejewska, B. M.; Subroto, T.; Morton, J. A.; Porfyrakis, K.; Tzanakis, I.; Eskin, D. G.; Grobert, N.; Fezzaa, K.; Mi, J. Ultrafast Synchrotron X-Ray Imaging and Multiphysics Modelling of Liquid Phase Fatigue Exfoliation of Graphite under Ultrasound. Carbon N. Y. 2022, 186, 227-237. https://doi.org/10.1016/j.carbon.2021.10.014.
[86]. Dular, M.; Bachert, B.; Štoffel, B.; Sirok, B. Relationship between Cavitation Structures and Cavitation Damage. Wear 2004, 257, 1176-1184. https://doi.org/10.1016/j.wear.2004.08.004.
[87]. Morton, J. A.; Eskin, D. G.; Grobert, N.; Mi, J.; Porfyrakis, K.; Prentice, P.; Tzanakis, I. Effect of Temperature and Acoustic Pressure During Ultrasound Liquid-Phase Processing of Graphite in Water. JOM 2021, 73, 3745-3752. https://doi.org/10.1007/s11837-021-04910-9.
[88]. Hauptmann, M.; Struyf, H.; De Gendt, S.; Glorieux, C.; Brems, S. Evaluation and Interpretation of Bubble Size Distributions in Pulsed Megasonic Fields. J. Appl. Phys. 2013, 113, 184902. https://doi.org/10.1063/1.4803858.
[89]. Kim, W.; Kim, T. H.; Choi, J.; Kim, H. Y. Mechanism of Particle Removal by Megasonic Waves. Appl. Phys. Lett. 2009, 94, 081908. https://doi.org/10.1063/1.3089820.
[90]. Morton, J. A.; Khavari, M.; Qin, L.; Maciejewska, B. M.; Tyurnina, A. V.; Grobert, N.; Eskin, D. G.; Mi, J.; Porfyrakis, K.; Prentice, P.; Tzanakis, I. New Insights into Sono-Exfoliation Mechanisms of Graphite: In Situ High-Speed Imaging Studies and Acoustic Measurements. Mater. Today 2021, 49, 10-22. https://doi.org/10.1016/j.mattod.2021.05.005.
[91]. Hauptmann, M.; Frederickx, F.; Struyf, H.; Mertens, P.; Heyns, M.; De Gendt, S.; Glorieux, C.; Brems, S. Enhancement of Cavitation Activity and Particle Removal with Pulsed High Frequency Ultrasound and Supersaturation. Ultrason. Sonochem. 2013, 20, 69-76. https://doi.org/10.1016/j.ultsonch.2012.04.015.
[92]. Han, S. Y.; Yerriboina, N. P.; Sahoo, B. N.; Kang, B. K.; Klipp, A.; Park, J. G. Effect of Surfactant in Gas Dissolved Cleaning Solutions on Acoustic Bubble Dynamics. Solid State Phenom. 2021, 314, 197-201. https://doi.org/10.4028/www.scientific.net/SSP.314.197.
[93]. Seo, H. B.; Lee, S. Y. High-Concentration Nanobubble Generation by Megasonic Cavitation and Atomization. Colloids Interface Sci. Commun. 2023, 52, 100687. https://doi.org/10.1016/j.colcom.2022.100687.
[94]. Ahmed, H.; Rezk, A. R.; Carey, B. J.; Wang, Y.; Mohiuddin, M.; Berean, K. J.; Russo, S. P.; Kalantar-zadeh, K.; Yeo, L. Y. Ultrafast Acoustofluidic Exfoliation of Stratified Crystals. Adv. Mater. 2018, 30, 1704756. https://doi.org/10.1002/adma.201704756.
[95]. Gale, G. W.; Busnaina, A. A. Roles of Cavitation and Acoustic Streaming in Megasonic Cleaning. Part. Sci. Technol. 1999, 17, 229-238. https://doi.org/10.1080/02726359908906815.
[96]. Mohiuddin, M.; Wang, Y.; Zavabeti, A.; Syed, N.; Datta, R. S.; Ahmed, H.; Daeneke, T.; Russo, S. P.; Rezk, A. R.; Yeo, L. Y.; Kalantar-Zadeh, K. Liquid Phase Acoustic Wave Exfoliation of Layered MoS₂: Critical Impact of Electric Field in Efficiency. Chem. Mater. 2018, 30, 5593-5601. https://doi.org/10.1021/acs.chemmater.8b01506.
[97]. Rezk, A. R.; Ahmed, H.; Ramesan, S.; Yeo, L. Y. High Frequency Sonoprocessing: A New Field of Cavitation-Free Acoustic Materials Synthesis, Processing, and Manipulation. Adv. Sci. 2021, 8, 2001983. https://doi.org/10.1002/advs.202001983.
[98]. Ahmed, M.; Ahmed, H.; Rezk, A. R.; Yeo, L. Y. Rapid Dry Exfoliation Method for Tuneable Production of Molybdenum Disulphide Quantum Dots and Large Micron-Dimension Sheets. Nanoscale 2019, 11, 11626-11633. https://doi.org/10.1039/c9nr04255e.
[99]. Telkhozhayeva, M.; Teblum, E.; Konar, R.; Girshevitz, O.; Perelshtein, I.; Aviv, H.; Tischler, Y. R.; Nessim, G. D. Higher Ultrasonic Frequency Liquid Phase Exfoliation Leads to Larger and Monolayer to Few-Layer Flakes of 2D Layered Materials. Langmuir 2021, 37, 4504-4514. https://doi.org/10.1021/acs.langmuir.0c03668.
[100]. L. Kuo, V. K. Sangwan, S. V. Rangnekar, T.-C. Chu, D. Lam, Z. Zhu, L. J. Richter, R. Li, B. M. Szydlowska, J. R. Downing, B. J. Luijten, L. J. Lauhon, and M. C. Hersam, “All-print ed ultrahigh-responsivity MoS2 nanosheet photodetectors enabled by megasonic exfoliation,” Adv. Mater., 34, 2203772 (2022).
[101]. J. W. T. Seo, J. Zhu, V. K. Sangwan, E. B. Secor, S. G. Wallace, M. C. Hersam, ACS Ap pl. Mater. Interfaces 2019, 11, 5675.
[102]. J. Kim, D. Rhee, O. Song, M. Kim, Y. Kwon, D. Lim, I. Kim, v. Mazanek, L. Valdman, Z. Sofer, J. Cho, J. Kang. Advanced Materials 2021, 34, 2106110.
[103]. R. F. Hossain, I. G. Deaguero, T. Boland, A. B. Kaul, npj 2D Mater. Appl. 2017, 1, 28.
[104]. Z. Lin, Y. Liu, U. Halim, M. Ding, Y. Liu, Y. Wang, C. Jia, P. Chen, X. X. Duan, C. Wang, F. Song, M. Li, C. Wan, Y. Huang, X. X. Duan, Nature 2018, 562, 254.
[105]. J. Li, M. M. Naiini, S. Vaziri, M. C. Lemme, M. Östling, Adv. Funct. Mater. 2014, 24, 652 4.
[106]. F. I. Alzakia, W. Jonhson, J. Ding, S. C. Tan, ACS Appl. Mater. Interfaces 2020, 12, 288 40.
[107]. Y. Zhao, V. Wang, D.-H. Lien & A. Javey, Nature Electronics 2020, 3, 612-621.
[108]. D.-H. Lien, M. Amani, S. B. Desai, G. H. Ahn, K. Han, J.-H. He, J. W. Ager III, M. C. Wu & A. Javey, Nature Comm. 2018, 9, 1229.
[109]. J. Cho, M. Amani, D. H. Lien, H. Kim, M. Yeh, V. Wang, C. Tan, A. Javey, Adv. Funct. Mater 2020, 30, 1907941.
[110]. S. H. Cho, J. Sung, I. Hwang, R. H. Kim, Y. S. Choi, S. S. Jo, T. W. Lee, C. P., Adv Mate rials 2012, 24, 4540-4546.
[111]. S. R. Forrest, S. Lee, Q. Burlingame. Organic electroluminescent materials and dev ices. U.S. Pat. No. 10,290,816 B2, Nov. 9, 2016.
[112]. R. Sharma, P. M. Pattison, J. F. Kaeding, S. Nakamura. Semiconductor light-emitting device. PCT Patent Application Publication No. WO2006/086387 A2, Feb. 7, 2006.
[113]. Y. Shimuzu, K. Sakano, Y. Noguchi, T. Moriguchi. Light emitting device with blue light LED and phosphor components, U.S. Pat. No. 7,531,960 B2, Mar. 5, 2007.
[114]. M. C. Hersam, J.-W. T. Seo, J. Zhu. Two-dimensional semiconductor based printable optoelectronic inks, fabricating methods and applications of same. U.S. Patent Application Publication No. US2021/0398808 A1, Sep. 27, 2019.
[115]. T. Yamazaki. Display apparatus and electronic device with light emitting device drive circuit including transistors with different semiconductor materials. U.S. Pat. No. 11,710,456 B2. Jul. 20, 2021.
[116]. H.-W. Yang, C.-G. Choi. Method of manufacturing capacitor, method of manufacturing organic light emitting display device including the capacitor, and organic light emitting display device manufactured by using the method. U.S. Pat. No. 9,349,996 B2, Jul. 9, 2015.

What is claimed is:

1. A method of forming a nanomaterial ink, comprising:
providing an as-prepared (AP) semiconductor ink containing first nanosheets of at least one semiconductor; and
megasonically exfoliating the AP semiconductor ink to form a megasonicated (MS) semiconductor ink containing second nanosheets of the at least one semiconductor.

2. The method of claim 1, wherein said providing the AP semiconductor ink comprises:
electrochemically intercalating crystals of the at least one semiconductor to obtain intercalated crystals of the at least one semiconductor;
exfoliating the intercalated crystals of the at least one semiconductor in a first solvent using bath sonication to obtain a suspension of exfoliated nanosheets of the at least one semiconductor; and
performing solvent transfer via centrifugation to disperse the exfoliated nanosheets of the at least one semiconductor in a second solvent while discarding supernatant, thereby forming the AP semiconductor ink containing the first nanosheets of the at least one semiconductor.

3. The method of claim 2, wherein the at least one semiconductor comprises:
elemental semiconductors including phosphorene, germanene, tellurene, selenene, and/or stanene;
monochalcogenides including GeS, InSe, GaTe, PbTe, SnS, and/or SnSe;
dichalcogenides including MoS₂, WSe₂, TaS₂, ReS₂, and/or MoTe₂;
trichalcogenides including NbSe₃, GaInS₃, Bi₂Se₃, and/or In₂Se₃;
2D semiconducting oxides including MnO₃ and/or V₂O₅;
2D semiconducting metal chalcophosphates including SnP₂Se₆, Sn₂P₂Se₆, NiPS₃, ZnPS₃, FePS₃;
2D metal halides including CrI₃, NiI₂, RuCl₃, VI₃; and/or
semiconducting MXenes including Mn₂CO₂, Ti₂C, Sc₂CF₂, and/or Cr₂CF₂.

4. The method of claim 2, wherein the first solvent contains polyvinylpyrrolidone (PVP) dissolved in dimethylformamide (DMF), N-methyl-2-pyrrolidone (NMP), propylene carbonate (PC), N-cyclohexyl-2-pyrrolidone (CHP), dimethylcarbonate (DMC), and/or dimethyl sulfoxide (DMSO). In one embodiment, the first solvent contains a stabilizing agent comprising small molecule stabilizers including bile salts (e.g., sodium cholate), linear chain surfactants (e.g., sodium dodecyl sulfate), and/or pyrene-derivative salts (e.g., 1-pyrenesulfonic acid); and/or polymers including polyvinylpyrrolidone (PVP), Triton X-100, poly(ethylene oxide) (PEO), poly(propylene oxide) (PPO), and/or poloxamers.

5. The method of claim 4, wherein said discarding the supernatant comprises removing excess PVP and precipitating poorly exfoliated semiconductor.

6. The method of claim 5, wherein each of the second nanosheets has a residual PVP coating on its nanosheet surface.

7. The method of claim 2, wherein the second solvent contains water, methanol, ethanol, isopropanol (IPA), butanol, acetone, acetonitrile, triethanolamine, terpineol, Cyrene, dimethylformamide (DMF), N-methyl-2-pyrrolidone (NMP), propylene carbonate (PC), N-cyclohexyl-2-pyrrolidone (CHP), dimethylcarbonate (DMC), and/or dimethyl sulfoxide (DMSO).

8. The method of claim 1, wherein said megasonically exfoliating the AP semiconductor ink is performed in a megasonicator having an acoustic medium containing a water bath, wherein the AP semiconductor ink is poured into a quartz liner tank installed inside the water bath.

9. The method of claim 8, wherein the quartz liner tank has a slant-bottom quartz liner fabricated such wall thickness and slope of the bottom of the quartz liner tank enable maximum transfer of acoustic energy from the water bath to the AP semiconductor ink in the quartz liner tank.

10. The method of claim 1, wherein said megasonically exfoliating the AP semiconductor ink is performed in a megasonicator having an acoustic medium containing a water bath, wherein the AP semiconductor ink is injected into a sealed plastic pouch placed inside the water bath.

11. The method of claim 10, wherein the sealed plastic pouch is solvent resistant and thin enough to ensure maximum transfer of acoustic energy from the water bath to the AP semiconductor ink in the sealed plastic pouch.

12. A nanomaterial ink, being formed by the method of claim 1.

13. The nanomaterial ink of claim 12, wherein the second nanosheets in the MS semiconductor ink are significantly thinner than the first nanosheets in the AP semiconductor ink.

14. The nanomaterial ink of claim 13, wherein the second nanosheets are averagely of monolayer nanosheets, and the first nanosheets are averagely of multilayer nanosheets.

15. The nanomaterial ink of claim 13, wherein the second nanosheets have a log-normal mean thickness of about 0.75 nm, and the first nanosheets have a log-normal mean thickness of about 2.3 nm.

16. The nanomaterial ink of claim 12, wherein each of the second nanosheets has a residual polymer coating on its nanosheet surface.

17. The nanomaterial ink of claim 12, wherein the optical absorbance spectrum of the second nanosheets has A and B exciton peaks that are blue-shifted and narrower compared to those of the first nanosheets.

18. The nanomaterial ink of claim 17, wherein the A exciton peak shifts from about 675 nm of the first nanosheets to about 650 nm of the second nanosheets, wherein the A exciton peak of about 650 nm corresponds to that of monolayer nanosheets.

19. The nanomaterial ink of claim 12, wherein the monolayer fraction in the MS semiconductor ink is about 68% of the total number of flakes, as calculated from optical absorption spectroscopy analysis, and the monolayer fraction in the AP semiconductor ink is about 2% of the total number of flakes.

20. The nanomaterial ink of claim 12, wherein the second nanosheets maintain high crystallinity after megasonication.

21. The nanomaterial ink of claim 12, wherein the distance between the in-plane (E¹_{2g}) and out-of-plane (A_{1g}) peaks of Raman spectra of the second nanosheets is about 19.5 cm⁻¹, and wherein the distance between the E¹_{2g} and A_{1g} peaks of Raman spectra of the first nanosheets to 22.5 cm⁻¹.

22. The nanomaterial ink of claim 12, wherein the photoluminescence (PL) intensity of the first nanosheets is significantly lower than that of the second nanosheets.

23. The nanomaterial ink of claim 12, wherein the A exciton PL peak of the first nanosheets is centered at about 1.8 eV, which is indicative of a trion-dominated resonance that is corresponding to the PL of multilayer nanosheets.

24. The nanomaterial ink of claim 12, wherein the spectral shape of the PL of the second nanosheets strongly resembles that of a mechanically exfoliated MoS₂ monolayer.

25. The nanomaterial ink of claim 12, wherein the spectral peak of the PL of the second nanosheets is positioned at 1.90 eV, which reflects the A exciton direct bandgap transition at the K point of the Brillouin zone.

26. A device, comprising:
at least one element formed of the nanomaterial ink according to claim 12 on a substrate.

27. The device of claim 26, wherein the at least one element is formed by dropcasting of the nanomaterial ink on the substrate.

28. The device of claim 26, further comprising electrodes coupled with the at least one element.

29. The device of claim 26, wherein the device is an electronic device including a transistor, a memristor, a diode, a power converter, a sensor, a battery, a resistor, integrated circuit elements, or combinations of them.

30. The device of claim 26, wherein the device is an optoelectronic device including a photodetector, a photosensor, a photodiode, a solar cell, a phototransistor, a light-emitting diode, a laser diode, integrated optical circuit (IOC) elements, a photoresistor, a charge-coupled imaging device, or combinations of them.

31. The device of claim 24, wherein the device is a vertical metal-semiconductor-insulator-metal (MSIM) device.

32. The device of claim 31, wherein the device comprises:
a gate electrode formed of a transparent conductive material on the glass substrate;
a dielectric film formed of Al₂O₃ on the gate electrode by atomic layer deposition (ALD);
a semiconductor film formed of the second nanosheets on the dielectric film by dropcasting the nanomaterial ink; and
a source electrode formed of a metal material on top of the semiconductor film.

33. The device of claim 32, wherein the transparent conductive material comprises transparent conducting oxides including fluorine doped tin oxide (FTO) and indium tin oxide (ITO).

34. The device of claim 32, wherein the metal material comprises gold, silver, chromium, indium, nickel, aluminum, platinum, palladium, bismuth, and/or titanium.

35. The device of claim 32, wherein the semiconductor film has a thickness in a range of about 1-100 nm.

36. The device of claim 32, wherein the photoluminescence (PL) intensity of the semiconductor film is peaked at 1.89 eV.

37. The device of claim 36, wherein the PL intensity of the semiconductor film increases with increasing film thickness while the PL peak remains at about 1.89 eV.

38. The device of claim 32, wherein the direct-bandgap character of individual monolayer nanosheets is retained in the composite, semiconductor film independently of film thickness.

39. The device of claim 32, wherein the MSIM device is configured to achieve electroluminescence (EL) through oscillatory bipolar carrier injection from the source electrode into the semiconductor film upon application of an alternating current (AC) bias to the gate electrode.

40. The device of claim 39, wherein the EL intensity of the MSIM device increases with the thickness of the semiconductor film.

41. The device of claim 39, wherein in operation, a waveform generator connected to a high bandwidth (1 MHz) voltage amplifier is used to apply a bipolar square wave signal V_{g} to the gate electrode while the source electrode is grounded.

42. The device of claim 41, wherein the square wave is centered about V_{g}=0 V with amplitudes in a range of about ±1 to about ±50 V and frequencies (f) in a range of about 1 to about 600 kHz.

43. The device of claim 42, wherein while applying the square wave with V_{g}=±20 V and f=100 kHz, the semiconductor EL is peaked at about 1.88 eV, indicating that the EL is emitted from a similar excitonic state as the semiconductor PL.

44. The device of claim 41, wherein the EL intensity of the MSIM device is modulatable by the square wave voltage parameters.

45. The device of claim 44, wherein the EL intensity of the MSIM device increases linearly with frequency due to an increased number of voltage transitions per unit time.

46. The device of claim 44, wherein the EL intensity of the MSIM device increases as a function of V_{g} above the turn-on voltage.

47. The device of claim 44, wherein the EL spectra of the semiconductor film red shift slightly with increasing frequency and voltage amplitude.

48. The device of claim 44, wherein measuring EL with decreasing frequency from 400 kHz to 50 kHz results in a blue shifting of the EL peaks, indicating that any charge trapping or heating effects are reversible.

49. The device of claim 44, wherein the semiconductor film shows uniform EL over an entire active device region between the source electrode and the gate electrodes, with the EL intensity increasing with frequency.

50. The device of claim 44, wherein the emission area in the MSIM device is directly determined by the patterned electrodes due to the vertical device architecture and sufficiently conductive semiconductor film with monolayer properties.

51. The device of claim 39, wherein the vertical MSIM device is usable as pixels in miniaturized light sources including micro light emitting diodes (micro-LEDs).
